(19) United States
(12) Patent Application Publication
(10) Pub. No.: US 2024/0067663 A1
(43) Pub. Date: Feb. 29, 2024

(54) YTTRIUM COMPOUND, SOURCE MATERIAL FOR FORMING YTTRIUM-CONTAINING FILM, AND METHOD OF MANUFACTURING INTEGRATED CIRCUIT DEVICE USING THE SAME

(71) Applicant: SAMSUNG ELECTRONICS CO., LTD., Suwon-si (KR)

(72) Inventors: Hyunwoo KIM, Suwon-si (KR); Kazuki HARANO, Tokyo (JP); Kiyoshi MURATA, Tokyo (JP); Haruyoshi SATO, Tokyo (JP); Seungmin RYU, Suwon-si (KR); Gyuhee PARK, Suwon-si (KR); Younjoung CHO, Suwon-si (KR); Atsushi YAMASHITA, Tokyo (KR)

(73) Assignee: ADEKA CORPORATION, Tokyo (JP)

(21) Appl. No.: 18/231,339

(22) Filed: Aug. 8, 2023

(30) Foreign Application Priority Data
Aug. 9, 2022 (KR) 10-2022-0099505

(51) Int. Cl. C07F 5/00; C01F 17/218; H01L 21/02

(52) U.S. Cl. CPC C07F 5/003; C01F 17/218; H01L 21/02192; H01L 21/02205; H01L 21/02271; H01L 21/0228; C23C 16/405

(57) ABSTRACT

An yttrium compound, a method of manufacturing an integrated circuit device, and a raw material for forming an yttrium-containing film, the yttrium compound being represented by the following General formula (1):

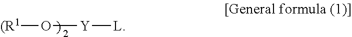

### CROSS-REFERENCE TO RELATED APPLICATION

This application is based on and claims priority under 35 U.S.C. § 119 to Korean Patent Application No. 10-2022-0099505, filed on Aug. 9, 2022, in the Korean Intellectual Property Office, the disclosure of which is incorporated by reference herein in its entirety.

### BACKGROUND

### 1. Field

Embodiments relate to an yttrium compound, a source material for forming an yttrium-containing film, and a method of manufacturing an integrated circuit device using the yttrium-containing film.

### 2. Description of the Related Art

Due to the development of electronics technology, down-scaling of semiconductor devices is rapidly progressing in recent years, and accordingly, patterns constituting electronic devices are being miniaturized.

### SUMMARY

The embodiments may be realized by providing an yttrium compound represented by the following General formula (1):

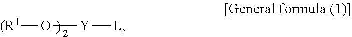

wherein, in General formula (1), R¹ is an unsubstituted C1-C8 straight-chain or branched alkyl group or a fluorine-substituted C1-C8 straight-chain or branched alkyl group, and L is a group represented by General formula (L-1) or General formula (L-2),

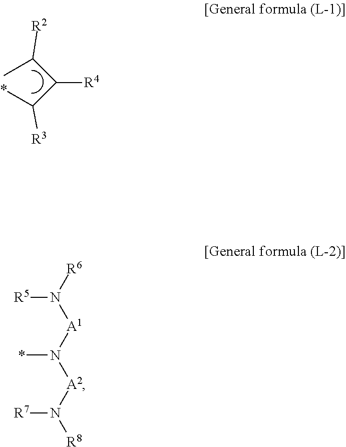

wherein, in General formula (L-1), R² and R³ are each independently a substituted or unsubstituted C1-C8 straight-chain or branched alkyl group or a group represented by General formula (L-3) or General formula (L-4), R⁴ is a hydrogen atom (H) or a substituted or unsubstituted C1-C5 straight-chain or branched alkyl group, and * indicates a bonding position, wherein, in General formula (L-2), R⁵, R⁶, R⁷, and R⁸ are each independently a substituted or unsubstituted C1-C5 straight-chain or branched alkyl group, A¹ and A² are each independently a substituted or unsubstituted C1-C5 alkanediyl group, and * indicates a bonding position,

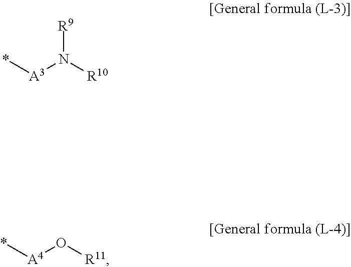

wherein, in General formulas (L-3) and (L-4), R⁹, R¹⁰, and R¹¹ are each independently a substituted or unsubstituted C1-C5 straight-chain or branched alkyl group, A³ and A⁴ are each independently a substituted or unsubstituted C1-C8 alkanediyl group, and * indicates a binding position.

The embodiments may be realized by providing a method of manufacturing an integrated circuit device, the method comprising forming an yttrium-containing film on a substrate using an yttrium compound represented by General formula (1):
wherein, in General formula (1), R¹ is an unsubstituted C1-C8 straight-chain or branched alkyl group or a fluorine-substituted C1-C8 straight-chain or branched alkyl group, and L is a group represented by General formula (L-1) or General formula (L-2),
wherein, in General formula (L-1), R² and R³ are each independently a substituted or unsubstituted C1-C8 straight-chain or branched alkyl group or a group represented by General formula (L-3) or General formula (L-4), R⁴ is a hydrogen atom (H) or a substituted or unsubstituted C1-C5 straight-chain or branched alkyl group, and * indicates a bonding position, wherein, in General formula (L-2), R⁵, R⁶, R⁷, and R⁸ are each independently a substituted or unsubstituted C1-C5 straight-chain or branched alkyl group, A¹ and A² are each independently a substituted or unsubstituted C1-C5 alkanediyl group, and * indicates a bonding position,
wherein, in General formulas (L-3) and (L-4), R⁹, R¹⁰, and R¹¹ are each independently a substituted or unsubstituted C1-C5 straight-chain or branched alkyl group, A³ and A⁴ are each independently a substituted or unsubstituted C1-C8 alkanediyl group, and * indicates a binding position.

The embodiments may be realized by providing a raw material for forming an yttrium-containing film, the raw material comprising an yttrium compound represented by General formula (1):
wherein, in General formula (1), R¹ is an unsubstituted C1-C8 straight-chain or branched alkyl group or a fluorine-substituted C1-C8 straight-chain or branched alkyl group, and L is a group represented by General formula (L-1) or General formula (L-2),
wherein, in General formula (L-1), R² and R³ are each independently a substituted or unsubstituted C1-C8 straight-chain or branched alkyl group or a group represented by General formula (L-3) or General formula (L-4), R⁴ is a hydrogen atom (H) or a substituted or unsubstituted C1-C5 straight-chain or branched alkyl group, and * indicates a bonding position, wherein, in General formula (L-2), R⁵, R⁶, R⁷, and R⁸ are each independently a substituted or unsubstituted C1-C5 straight-chain or branched alkyl group, A¹ and A² are each independently a substituted or unsubstituted C1-C5 alkanediyl group, and * indicates a bonding position,
wherein, in General formulas (L-3) and (L-4), R⁹, R¹⁰, and R¹¹ are each independently a substituted or unsubstituted C1-C5 straight-chain or branched alkyl group, A³ and A⁴ are each independently a substituted or unsubstituted C1-C8 alkanediyl group, and * indicates a binding position.

### BRIEF DESCRIPTION OF THE DRAWINGS

Features will be apparent to those of skill in the art by describing in detail exemplary embodiments with reference to the attached drawings in which:

FIG. 1 is a flowchart of a method of manufacturing an integrated circuit device, according to an embodiment;

FIG. 2 is a flowchart of a method of forming an yttrium-containing film according to an embodiment;

FIGS. 3 to 6 are schematic diagrams each schematically illustrating a configuration of a deposition apparatus that may be used in a process of forming an yttrium-containing film in a method of manufacturing an integrated circuit device, according to an embodiment; and

FIGS. 7 and 8 are cross-sectional views of stages in a method of manufacturing an integrated circuit device, according to an embodiment.

### DETAILED DESCRIPTION

As used herein, the term “substrate” may refer to a substrate itself or a stack structure including a substrate and a predetermined layer or film formed on a surface thereof.

As used herein, the term “surface of a substrate” may denote an exposed surface of the substrate itself, or an outer surface of a predetermined layer or film formed on the substrate.

As used herein, “room temperature” is from about 20° C. to about 28° C., which may vary depending on the season.

As used herein, the abbreviation “Me” refers to a methyl group, the abbreviation “Et” refers to an ethyl group, the abbreviation “nPr” refers to a normal propyl group, the abbreviation “iPr” refers to an isopropyl group, and the abbreviation “nBu” refers to a normal butyl group or a linear butyl group, the abbreviation “sBu” refers to a sec-butyl group (1-methylpropyl group), the abbreviation “iBu” refers to an isobutyl group (2-methylpropyl group), the abbreviation “tBu” refers to a tert-butyl group (1,1-dimethylethyl group), and the abbreviation “Cp” refers to a cyclopentadienyl group.

Hereinafter, embodiments will be described in detail with reference to the accompanying drawings.

The yttrium compound according to an embodiment may be represented by the following General formula (1).

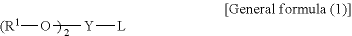

In General formula (1), R¹ may be, e.g., a straight-chain or branched alkyl group of C1-C8, or a fluorine atom (F)-containing alkyl group of C1-C8. In an implementation, R¹ may be or may include, e.g., an unsubstituted C1-C8 straight-chain or branched alkyl group or a fluorine-substituted C1-C8 straight-chain or branched alkyl group. L may be, e.g., a group represented by General formula (L-1) or General formula (L-2). As used herein, the term “or” is not an exclusive term, e.g., “A or B” would include A, B, or A and B.

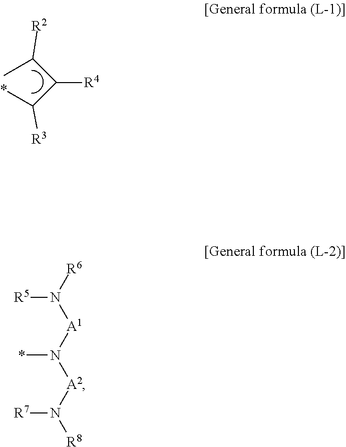

In General formula (L-1), R² and R³ may each independently be, e.g., a straight-chain or branched alkyl group of C1-C8 or a group represented by General formula (L-3) or General formula (L-4). In an implementation, R² and R³ may each independently be or include, e.g., a substituted or unsubstituted C1-C8 straight-chain or branched alkyl group or a group represented by General formula (L-3) or General formula (L-4). R⁴ may be, e.g., a hydrogen atom (H) or a straight-chain or branched alkyl group of C1-C5. In an implementation, R⁴ may be or may include, e.g., a hydrogen atom (H) or a substituted or unsubstituted C1-C5 straight-chain or branched alkyl group. * indicates a bonding position. As used herein, “substituted” refers to substitution with a suitable substituent.

In general formula (L-2), R⁵, R⁶, R⁷, and R⁸ may each independently be, e.g., a straight-chain or branched alkyl group of C1-C5. In an implementation, R⁵, R⁶, R⁷, and R⁸ may each independently be or include, e.g., a substituted or unsubstituted C1-C5 straight-chain or branched alkyl group. A¹ and A² may each independently be, e.g., an alkanediyl group of C1-C5. In an implementation, A¹ and A² may each independently be or include, e.g., a substituted or unsubstituted C1-C5 alkanediyl group. * indicates a bonding position,

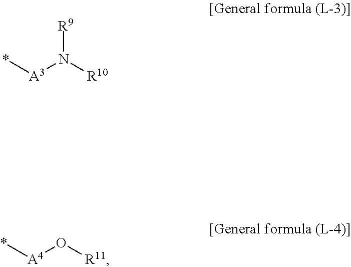

In General formulas (L-3) and (L-4), R⁹, R¹⁰, and R¹¹ may each independently be, e.g., a straight-chain or branched C1-C5 alkyl group. In an implementation, R⁹, R¹⁰, and R¹¹ may each independently be or include, e.g., a substituted or unsubstituted straight-chain or branched C1-C5 alkyl group. A³ and A⁴ may each independently be, e.g., a C1-C8 alkanediyl group. In an implementation, A³ and A⁴ may each independently be or include , e.g., a substituted or unsubstituted C1-C8 alkanediyl group. * indicates a binding position.

In an implementation, the C1-C5 alkyl group may include, e.g., a methyl group, an ethyl group, a propyl group, an isopropyl group, a butyl group, an isobutyl group, a sec-butyl group, a tert-butyl group, a pentyl group, an isopentyl group, or a neopentyl group.

In an implementation, the C1-C8 alkyl group may include, e.g., a hexyl group, a haptyl group, a 3-haptyl group, an isoheptyl group, a tert-haptyl group, an isooctyl group, a tert-octyl group, or a 2-ethylhexyl group, in addition to the C1-C5 alkyl group.

In an implementation, the C1-C8 fluorine atom (F)-containing or fluorine substituted alkyl group may include, e.g., a monofluoromethyl group, a difluoromethyl group, a trifluoromethyl group, a trifluoroethyl group, a trifluoropropyl group, a dimethyltrifluoroethyl group, a (trifluoromethyl) tetrafluoroethyl group, or a nonafluorotertiary butyl group.

In an implementation, the C1-C5 alkanediyl group may include, e.g., a methylene group, an ethylene group, a propane-1,3-diyl group, a propane-1,2-diyl group, a butane-1,4-diyl group, a butane-1,3-diyl group, a butane-2,3-diyl group, a pentane-1,3-diyl group, a pentane-1,4-diyl group, or a pentane-1,5-diyl group.

In an implementation, the C1-C8 alkanediyl group may include, e.g., in addition to the C1-C5 alkanediyl group, a hexane-1,1-diyl group, a hexane-1,2-diyl group, a hexane-1,3-diyl group, a hexane-1,4-diyl group, a hexane-1,5-diyl group, a hexane-1,6-diyl group, a heptane-1,7-diyl group, or an octane-1,8-diyl group.

In a thin film manufacturing process including an operation of vaporizing the compound of the General formula (1), a compound having a relatively high vapor pressure and a relatively low melting point may be used.

In the compound of General formula (1), R¹ and L may be selected so as to ensure a low melting point and a relatively high vapor pressure.

In an implementation, in the groups of General formulas (L-1) and (L-2), R² to R⁸, A¹, and A² may be selected so as to secure a low melting point and a relatively high vapor pressure.

In an implementation, in the groups of General formulas (L-3) and (L-4), R⁹ to R¹¹, A³, and A⁴ may be selected to ensure a low melting point and a relatively high vapor pressure.

With a view toward the vapor pressure of an yttrium compound being high and the thermal stability of the yttrium compound being high, R¹ may be, e.g., a C1-C5 alkyl group, a C1-C5 fluorine atom (F) containing alkyl group, or a C1-C5 fluoroalkyl group, e.g., a C2-C5 fluoroalkyl group.

With a view toward the productivity of high-quality thin film being increased when the yttrium compound having high thermal stability is used as a raw material for forming a thin film, R² may be, e.g., a C1-C5 alkyl group, a C3-C5 alkyl group, or a C3-C5 branched alkyl group, e.g., an isopropyl group or a tert-butyl group.

With a view toward the productivity of a high-quality thin film being increased when the yttrium compound is used as a source material for forming a thin film, R³ may be, e.g., a C1-C5 alkyl group, a group represented by the General formula (L-3), or a group represented by the General formula (L-4), e.g., a group represented by the General formula (L-3).

With a view toward the vapor pressure of the yttrium compound being high and the thermal stability of the yttrium compound being high, R⁴ may be, e.g., a hydrogen atom (H), a C1-C5 alkyl group, a methyl group, or an ethyl group, e.g., a methyl group.

With a view toward the productivity of a high-quality thin film being increased when the yttrium compound having high vapor pressure is used as a source material for forming a thin film, each of R⁵ to R⁸ may be, e.g., a C1-C3 alkyl group, a methyl group, or an ethyl group, e.g., a methyl group. R⁵ to R⁸ may be different groups from each other, or may be the same group having a high thermal stability of the yttrium compound.

With a view toward the vapor pressure of the yttrium compound being high and the productivity of a high-quality thin film being increased when the yttrium compound is used as a source material for forming a thin film, each of A¹ and A² may be, e.g., a C1-C3 alkanediyl group, an ethylene group, or propane-1,3-diyl group, e.g., an ethylene group. A¹ and A² may be different groups from each other, or may be the same group with high thermal stability of the yttrium compound.

With a view toward the vapor pressure of the yttrium compound being high and the productivity of a high-quality thin film being increased when the yttrium compound is used as a source material for forming a thin film, each of R⁹ to R¹¹ may be, e.g., a C1-C3 alkyl group, a methyl group, or an ethyl group, e.g., a methyl group.

With a view toward the thermal stability of the yttrium compound being high and the productivity of a high-quality thin film being increased when the yttrium compound is used as a source material for forming a thin film, A³ may be, e.g., a C1-C4 alkanediyl group or a C2-C3 alkanediyl group, e.g., a C3 alkanediyl group.

With a view toward the thermal stability of the yttrium compound being high and the productivity of a high-quality thin film being increased when the yttrium compound is used as a source material for forming a thin film, A⁴ may be, e.g., a C2-C5 alkanediyl group or a C3-C4 alkanediyl group, e.g., a C4 alkanediyl group.

The yttrium compound according to an embodiment may provide excellent thermal stability. In an implementation, an yttrium compound according to an embodiment may be used as an yttrium precursor in a chemical vapor deposition (CVD) process or an atomic layer deposition (ALD) process, and as the yttrium compound is transported from a storage container to a reaction chamber, the yttrium compound may be stably transported without being decomposed by heat.

In an implementation, the yttrium compound according to an embodiment may be transported to a reaction chamber for forming an yttrium-containing film, and the yttrium compound may not easily decompose by a process temperature in the reaction chamber and may not affect a surface reaction for forming the yttrium-containing film. In an implementation, when forming an yttrium-containing film using the yttrium compound according to an embodiment, a phenomenon of remaining unwanted foreign substances, e.g., carbon residue in the yttrium-containing film to be formed, may be suppressed, an yttrium-containing film of good quality may be formed, and accordingly, the productivity of a manufacturing process of the integrated circuit device including the yttrium-containing film may be improved.

Examples of the yttrium compound according to the embodiments may be represented by one of the following Chemical Formulas 1 to 69.

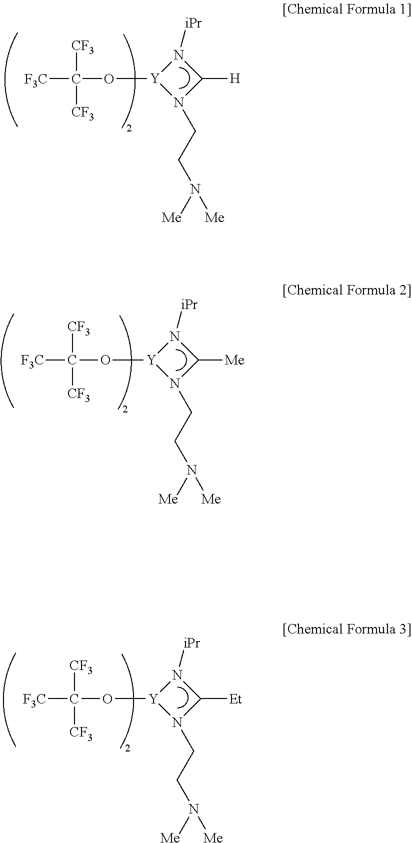

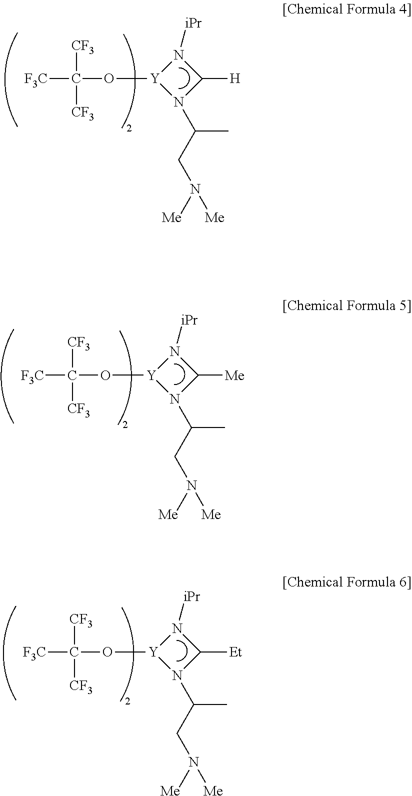

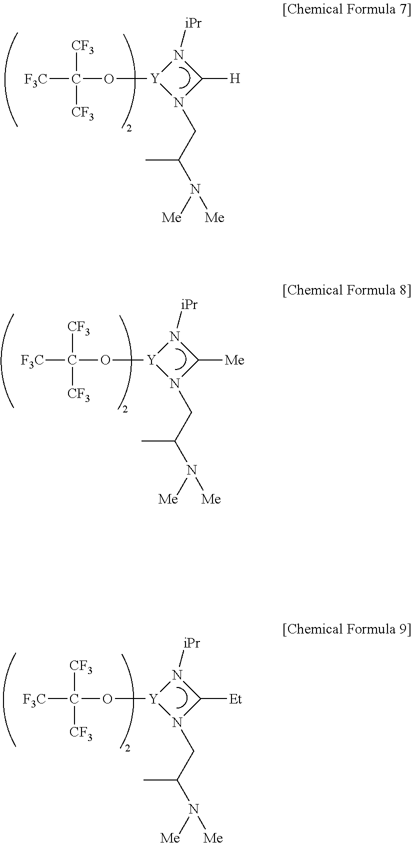

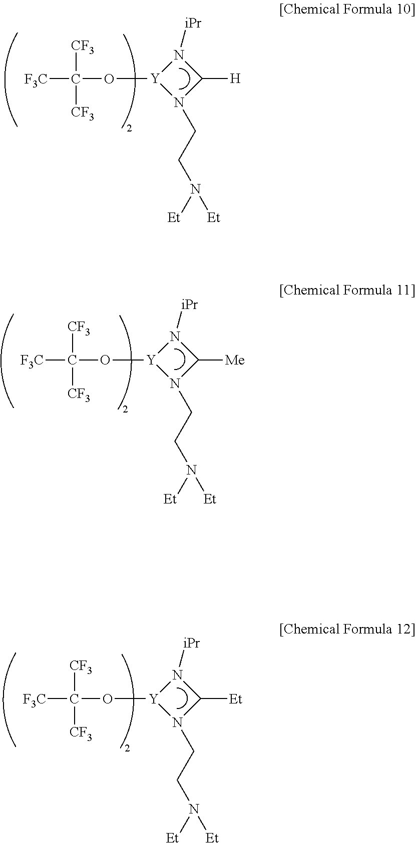

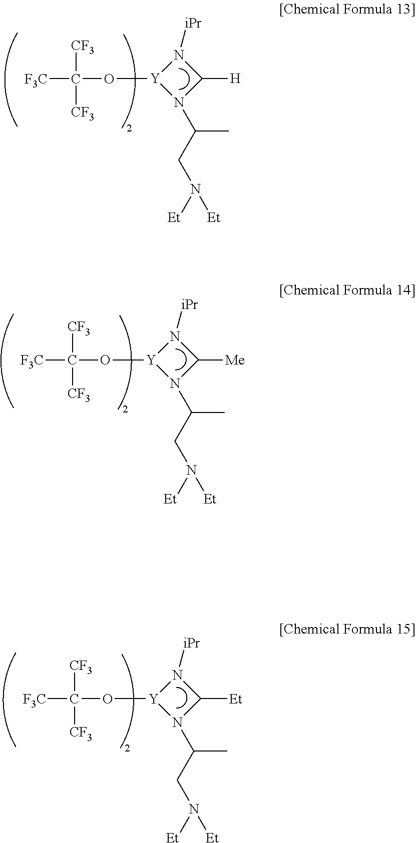

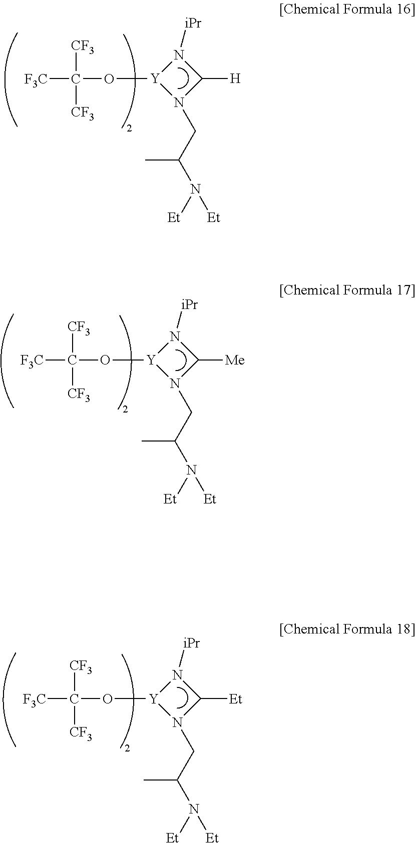

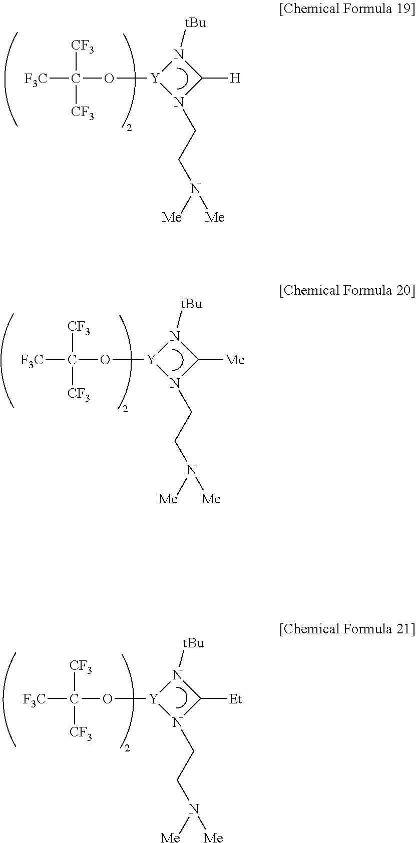

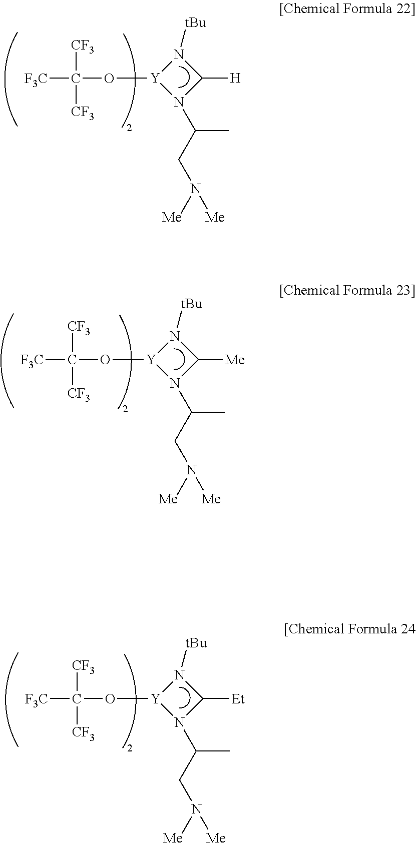

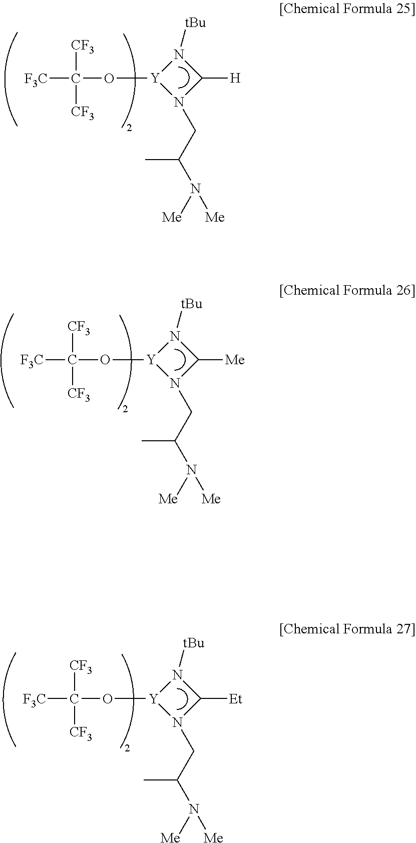

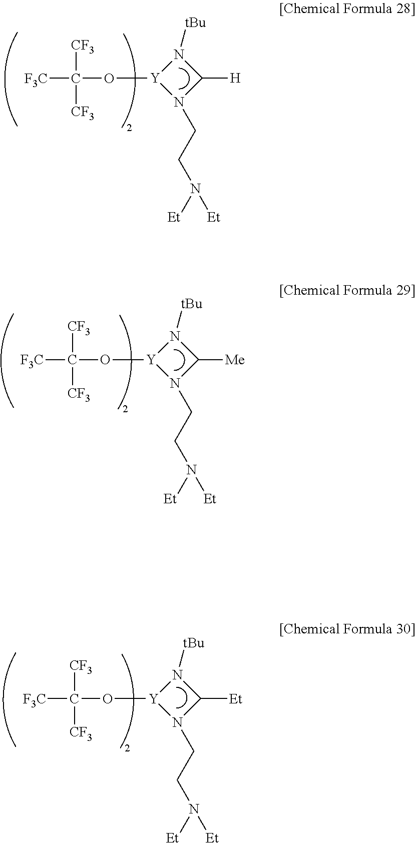

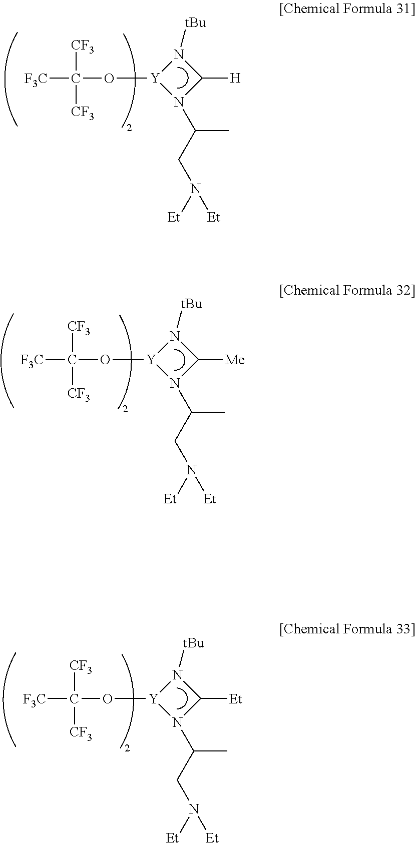

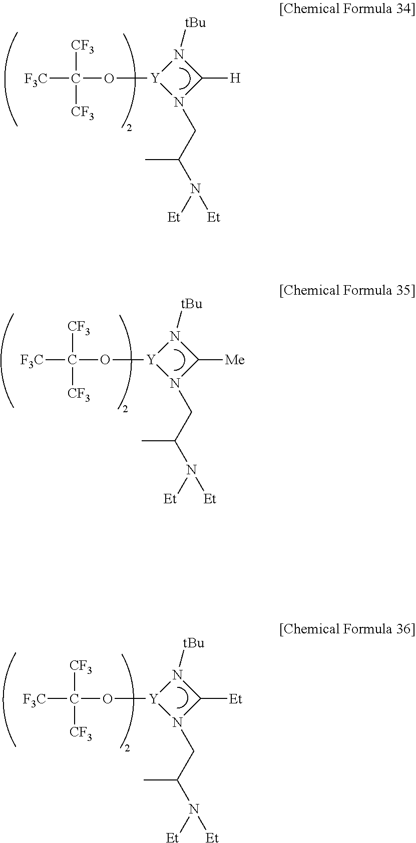

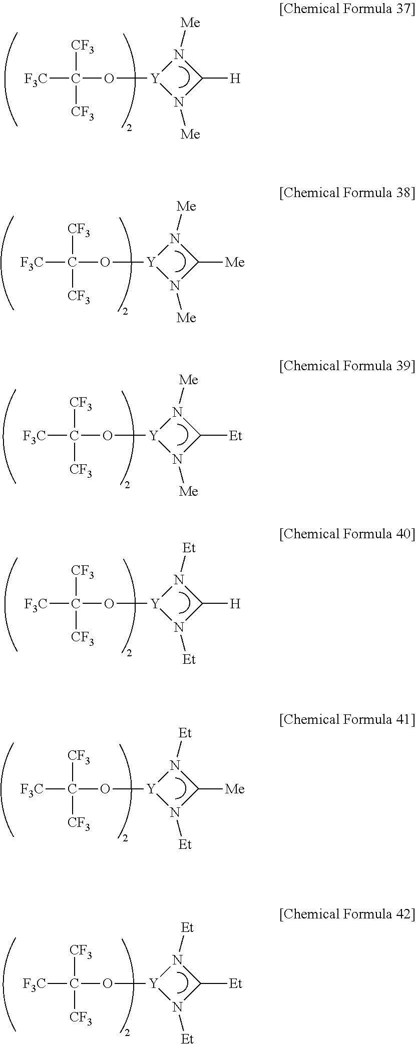

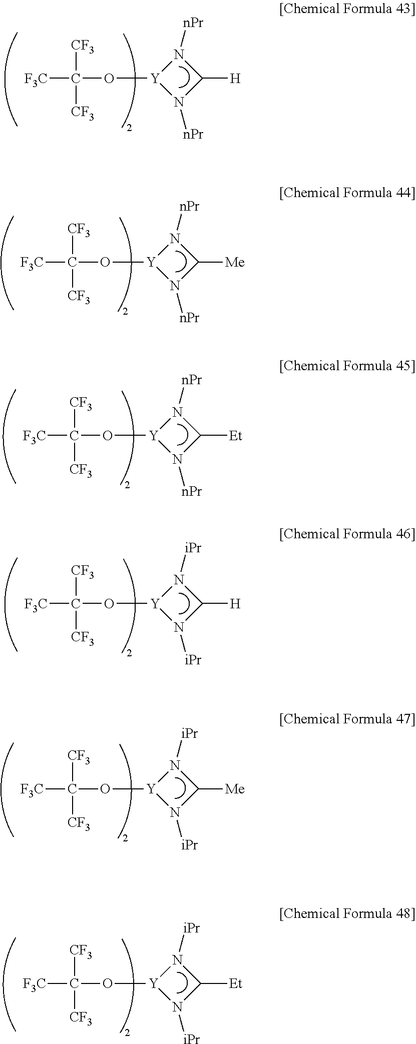

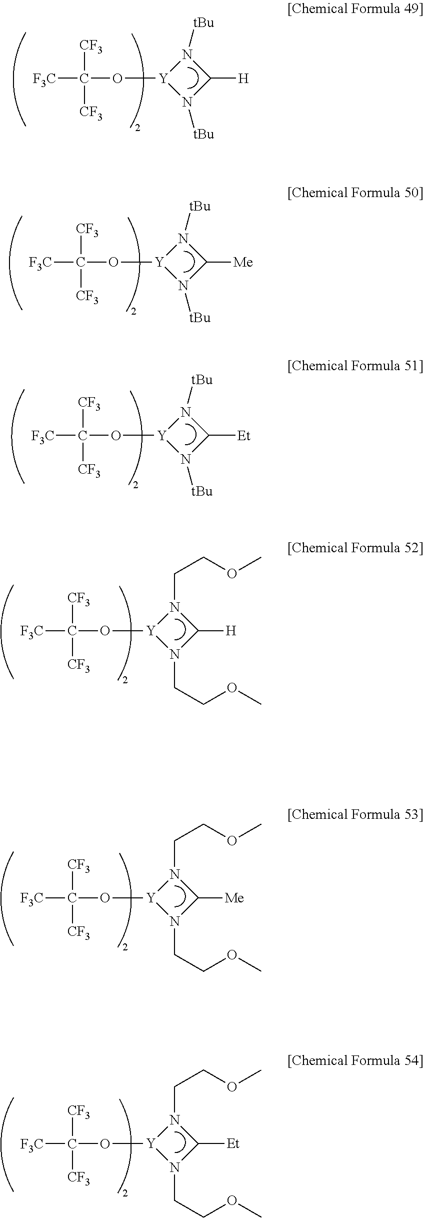

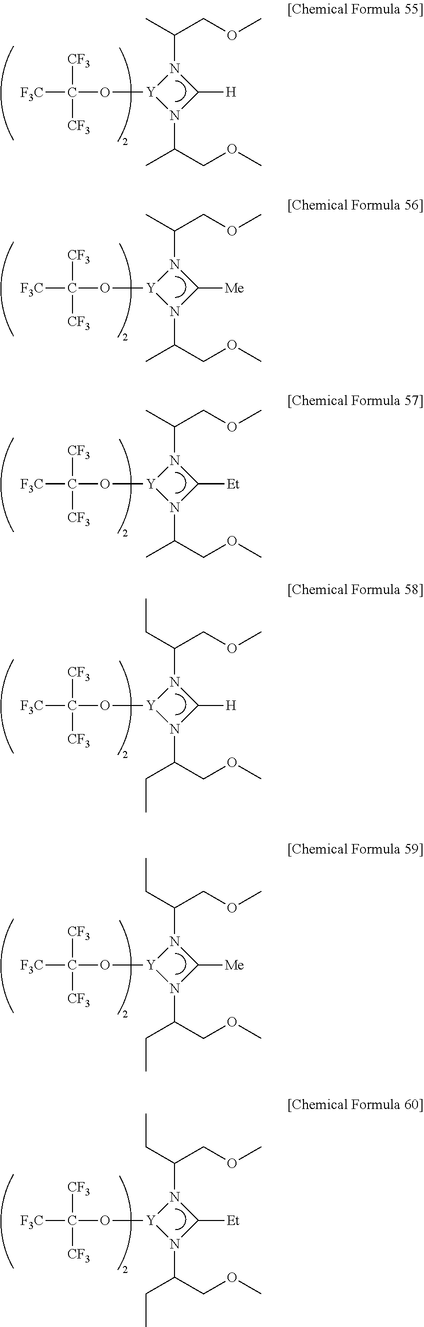

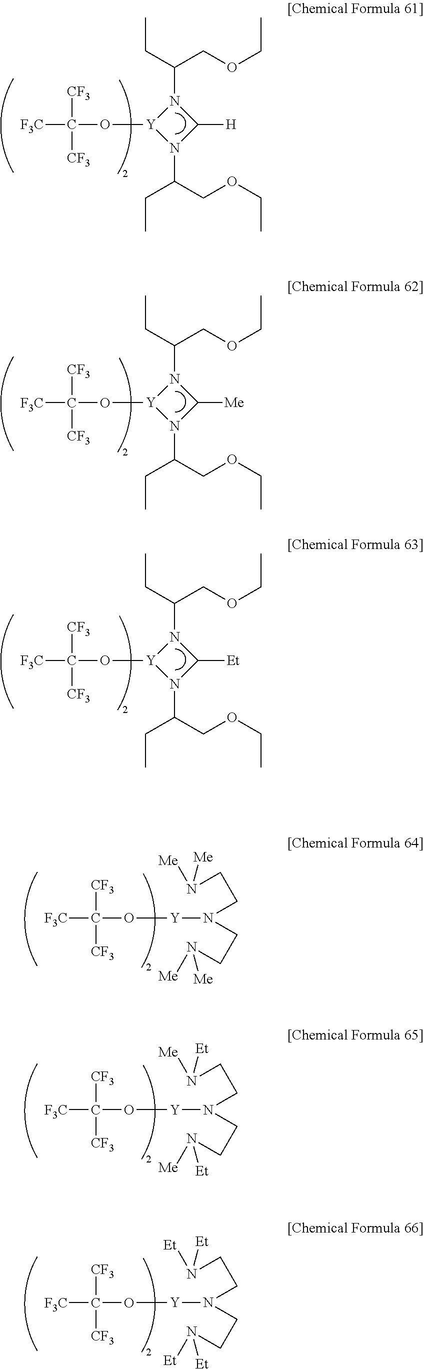

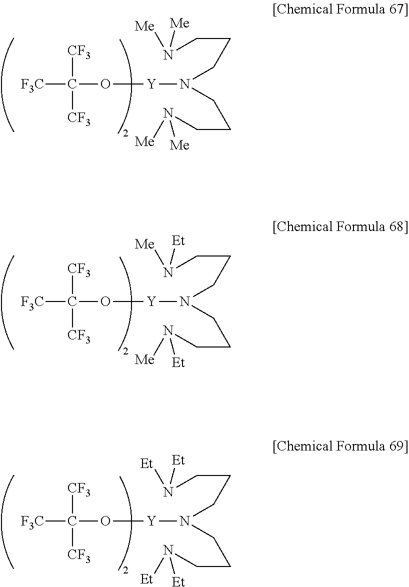

The yttrium compound of the General formula (1) may be synthesized by applying suitable reactions. In an implementation, tris[N,N-bis(trimethylsilyl)amide]yttrium, an amidinate compound having a desired structure, and an alcohol compound having a desired structure may react in a toluene solvent. After the reaction, the yttrium compound of the General formula (1) may be obtained by further purifying and refining a resultant product after removing the solvent.

The yttrium compound according to embodiments may be used as a source material suitable for a CVD process or an ALD process.

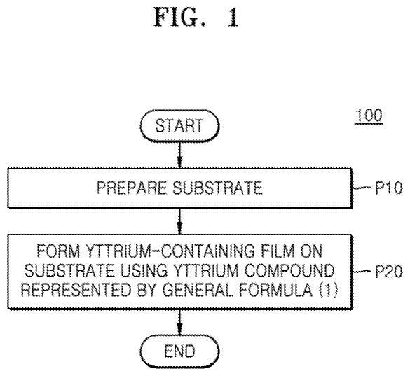

FIG. 1 is a flowchart of a method 100 of manufacturing an integrated circuit device, according to an embodiment.

Referring to FIG. 1, a substrate may be prepared in operation P10.

The substrate may include a semiconductor, ceramic, glass, metal, metal nitride, or a combination thereof. The semiconductor may include a semiconductor element, such as Si or Ge, or a compound semiconductor, such as SiGe, SiC, GaAs, InAs, or InP. The ceramic may include silicon nitride, tantalum nitride, titanium nitride, titanium oxide, niobium oxide, zirconium oxide, hafnium oxide, lanthanum oxide, or a combination thereof. Each of the metal and the metal nitride may include Ti, Ta, Co, Ru, Zr, Hf, La, or a combination thereof.

A surface of the substrate may have a flat, spherical, fibrous, or scalelike shape. In an implementation, the surface of the substrate may have a three-dimensional structure, such as a trench structure.

In operation P20 of FIG. 1, an yttrium-containing film may be formed on the substrate using a source material for forming an yttrium-containing film including the yttrium compound of the General formula (1).

The source material for forming an yttrium-containing film may include the yttrium compound according to an embodiment. In an implementation, the source material for forming an yttrium-containing film may include at least one yttrium compound among yttrium compounds represented by Chemical Formulas 1 to 69.

In an implementation, the source material for forming an yttrium-containing film may not include other metal compounds and semimetal compounds other than the yttrium compound represented by General Formula (1).

In an implementation, an yttrium-containing film to be formed may further include other metals in addition to yttrium. In an implementation, the yttrium-containing film to be formed may be a film further including a metal or a semimetal other than yttrium, and the source material for forming an yttrium-containing film may include the desired metal or semimetal. The source material may include a compound (hereinafter, may be referred to as “other precursor”) including the desired metal or semimetal in addition to the yttrium compound according to an embodiment. In an implementation, the source material for forming an yttrium-containing film may further include an organic solvent or a nucleophilic reagent in addition to the yttrium compound according to embodiments.

A CVD process or an ALD process may be used to form the yttrium-containing film according to operation P20 of FIG. 1. A source material for forming an yttrium-containing film including the yttrium compound according to the embodiments may be suitably used in a CVD process or an ALD process.

When the source material for forming an yttrium-containing film is used in a chemical vapor deposition process, the composition of the source material for forming the yttrium-containing film may be appropriately selected according to a transportation method thereof. A method of transporting the source material may include a gas transportation method or a liquid transportation method. In the gas transportation method, the source material may be vaporized and converted into a vapor state by heating or reducing pressure in a container (hereinafter, may be referred to as a “source material container”) in which a source material for forming an yttrium-containing film is stored, and the source material in a vapor state may be introduced into a chamber (hereinafter, may be referred to as a “deposition reaction unit”) in which the substrate is placed together with a carrier gas, such as argon, nitrogen, helium, or the like, used as needed. In the liquid transportation method, the source material may be transported in a liquid or solution state to a vaporization chamber and vaporized by heating and/or reducing pressure in the vaporization chamber to make vapor, and then the vapor may be introduced into the chamber.

When the gas transportation method is used to form an yttrium-containing film according to operation P20 of FIG. 1, the yttrium compound of the General formula (1) itself may be used as a source material for forming an yttrium-containing film. When the liquid transportation method is used to form an yttrium-containing film according to operation P20 of FIG. 1, the yttrium compound itself of the General formula (1) or a solution obtained by dissolving the yttrium compound of the General formula (1) in an organic solvent may be used as a source material for forming an yttrium-containing film. The source material for forming an yttrium-containing film may further include other precursors, nucleophilic reagents, or the like.

In an implementation, a multi-component chemical vapor deposition method may be used to form an yttrium-containing film in the method of manufacturing an integrated circuit device. In the multi-component chemical vapor deposition method, a method of independently vaporizing and supplying a source material for forming an yttrium-containing film for each component (hereinafter, may be referred to as a “single source method”), or a method of vaporizing and supplying a mixed source material in which a multi-component source material is mixed in advance to a desired composition (hereinafter, may be referred to as a “cocktail source method”) may be used. In the case of using the cocktail source method, a mixture of an yttrium compound according to an embodiment and another precursor or a mixed solution obtained by dissolving the mixture in an organic solvent may be used as a source material for forming an yttrium-containing film. The mixture or the mixed solution may further include a nucleophilic reagent.

In an implementation, suitable organic solvents may be used. In an implementation, as the organic solvent, acetic esters, such as ethyl acetate, butyl acetate, methoxyethyl acetate, and the like; ethers, such as tetrahydrofuran, tetrahydropyran, ethylene glycol dimethyl ether, triethylene glycol dimethyl ether, and dibutyl ether; ketones, such as methyl butyl ketone, methyl isobutyl ketone, ethyl butyl ketone, dipropyl ketone, diisobutyl ketone, methyl amyl ketone, cyclohexanone, and methylcyclohexanone; hydrocarbons, such as hexane, cyclohexane, methylcyclohexane, dimethylcyclohexane, ethylcyclohexane, heptane, octane, toluene, and xylene; hydrocarbons having a cyano group, such as 1-cyanopropane, 1-cyanobutane, 1-cyanohexane, cyanocyclohexane, cyanobenzene, 1,3-dicyanopropane, 1,4-dicyanobutane, 1,6-dicyanohexane, 1,4-dicyanocyclo hydrocarbons having a cyano group such as hexane (1,4-dicyanocyclohexane) and 1,4-dicyanobenzene; pyridine; lutidine, and the like may be used. The organic solvents described above may be used alone or as a mixed solvent of at least two types considering the solubility of a solute, a used temperature and boiling point, a relationship with a flash point, and the like.

When an organic solvent is included in the source material for forming an yttrium-containing film including the yttrium compound according to an embodiment, a total amount or concentration of the yttrium compound and other precursors may be in a range of about 0.01 mol/L to about 2.0 mol/L in the organic solvent, e.g., in a range of about 0.05 mol/L to about 1.0 mol/L. In an implementation, when the source material for forming an yttrium-containing film does not include other metal compounds and semimetal compounds other than the yttrium compound, the total amount may be the amount of the yttrium compound according to an embodiment, and when the source material for forming an yttrium-containing film further includes other metal compounds or semi-metal compounds, e.g., other precursors in addition to the yttrium compound, the total amount may be the sum of the amount of the yttrium compound and the amount of the other precursors.

When the multi-component chemical vapor deposition method is used to form an yttrium-containing film in the method of manufacturing an integrated circuit device, the type of other precursors that may be used together with the yttrium compound may include other suitable precursors used as a source material for forming an yttrium-containing film.

In an implementation, other precursors that may be used to form an yttrium-containing film in the method of manufacturing an integrated circuit device may include at least one organic coordination compound selected from an alcohol compound, a glycol compound, a β-diketone compound, a cyclopentadiene compound, and an organic amine compound, a silicone compound, or a metal compound.

In an implementation, the other precursors may include elements, e.g. lithium (Li), sodium (Na), potassium (K), magnesium (Mg), calcium (Ca), strontium (Sr), barium (Ba), titanium (Ti), zirconium (Zr), hafnium (Hf), vanadium (V), chromium (Cr), molybdenum (Mo), tungsten (W), manganese (Mn), iron (Fe), cobalt (Co), rhodium (Rh), iridium (Ir), nickel (Ni), platinum (Pt), copper (Cu), silver (Ag), gold (Au), zinc (Zn), aluminum (Al), germanium (Ge), tin (Sn), lead (Pb), antimony (Sb), bismuth (Bi), tantalum (Ta), niobium (Nb), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), ruthenium (Ru), lutetium (Lu), or the like.

The alcohol compound having an organic ligand of the other precursors may include, e.g., alkyl alcohols, such as methanol, ethanol, propanol, isopropyl alcohol, butanol, sec-butyl alcohol, isobutyl alcohol, tert-butyl alcohol, pentyl alcohol, isopentyl alcohol, and tert-pentyl alcohol; ether alcohols, such as 2-methoxyethanol, 2-ethoxyethanol, 2-butoxyethanol, 2-(2-methoxyethoxy) ethanol, 2-methoxy-1-methylethanol, 2-methoxy-1,1-dimethylethanol, 2-ethoxy-1,1-dimethylethanol, 2-isopropoxy-1,1-dimethylethanol, 2-butoxy-1,1-dimethylethanol, 2-(2-methoxyethoxy)-1,1-dimethylethanol, 2-propoxy-1,1-diethylethanol, 2-sec-butoxy-1,1-diethylethanol, and 3-methoxy-1,1-dimethylpropanol; and dialkylamino alcohols, such as dimethylaminoethanol, ethylmethylaminoethanol, diethylaminoethanol, dimethylamino-2-pentanol, ethylmethylamino-2-pentanol, dimethylamino-2-methyl-2-pentanol, ethylmethylamino-2-methyl-2-pentanol, diethylamino-2-methyl-2-pentanol, or the like.

A glycol compound that may be used as an organic coordination compound of the other precursors may include, e.g., 1,2-ethanediol, 1,2-propanediol, 1,3-propanediol, 2,4-hexanediol, 2,2-dimethyl-1,3-propanediol, 2,2-diethyl-1,3-propanediol, 1,3-butanediol, 2,4-butanediol, 2,2-diethyl-1,3-butanediol, 2-ethyl-2-butyl-1,3-propanediol, 2,4-pentanediol, 2-methyl-1,3-propanediol, 2-methyl-2,4-pentanediol, 2,4-hexanediol, 2,4-dimethyl-2,4-pentanediol, or the like.

A β-diketone compound that may be used as an organic coordination compound of the other precursors may include, e.g., alkyl-substituted β-diketones, such as acetylacetone, hexane-2,4-dione, 5-methylhexane-2,4-dione, heptane-2,4-dione), 2-methylheptane-3,5-dione, 5-methylheptane-2,4-dione, 6-methylheptane-2,4-dione, 2,2-dimethylheptane-3,5-dione, 2,6-dimethylheptane-3,5-dione, 2,2,6-trimethylheptane-3,5-dione, 2,2,6,6-tetramethylheptane-3,5-dione, octane-2,4-dione, 2,2,6-trimethyloctane-3,5-dione, 2,6-dimethyloctane-3,5-dione, 2,9-dimethylnonane-4,6-dione, 2-methyl-6-ethyldecane-3,5-dione, 2,2-dimethyl-6-ethyldecane-3,5-dione, etc.; fluorine-substituted alkyl β-diketones, such as 1,1,1-trifluoropentane-2,4-dione, 1,1,1-trifluoro-5,5-dimethylhexane-2,4-dione, 1,1,1,5,5,5-hexafluoropentane-2,4-dione, 1,3-diperfluorohexylpropane-1,3-dione, etc.; and ether-substituted β-diketones, such as 1,1,5,5-tetramethyl-1-methoxyhexane-2,4-dione, 22,2,6,6-tetramethyl-1-methoxyheptane-3,5-dione, 2,2,6,6-tetramethyl-1-(2-methoxyethoxy)heptane-3,5-dione, or the like.

A cyclopentadiene compound that may be used as an organic coordination compound of the other precursors may include, e.g., cyclopentadiene, methylcyclopentadiene, ethylcyclopentadiene, propylcyclopentadiene, isopropylcyclopentadiene, butylcyclopentadiene, sec-butylcyclopentadiene, isobutylcyclopentadiene, tert-butylcyclepentadiene, dimethylcyclopentadiene, tetramethylcyclopentadiene, or the like.

An organic amine compound that may be used as an organic coordination compound of the other precursors may include, e.g., methylamine, ethylamine, propylamine, isopropylamine, butylamine, sec-butylamine, tert-butylamine, isobutylamine, dimethylamine, diethylamine, dipropylamine, diisopropylamine, ethylmethylamine, propylmethylamine, isopropylmethylamine, or the like.

The other precursors may be suitable precursors, and a suitable method may be used to manufacture the other precursors. In an implementation, when an alcohol compound is used as an organic ligand, a precursor may be manufactured by reacting an inorganic salt or a hydrate thereof of the element described above with an alkali metal alkoxide of the corresponding alcohol compound. In an implementation, the inorganic salt of the element described above or its hydrate may include, e.g., a metal halide, acetic acid, etc. The alkali metal alkoxide may include, e.g., sodium alkoxide, lithium alkoxide, potassium alkoxide, etc.

In the case of using the single source method, a compound having a thermal and/or oxidative decomposition behavior similar to that of the yttrium compound according to an embodiment may be used as the other precursor. In the case of using the cocktail source method, a compound having a thermal and/or oxidative decomposition behavior is similar to that of the yttrium compound according to an embodiment, and also, that does not cause deterioration due to a chemical reaction during mixing may be used as the other precursor.

In forming the yttrium-containing film in the method of manufacturing an integrated circuit device, the source material for forming the yttrium-containing film may include a nucleophilic reagent. The nucleophilic reagent may help impart stability to the yttrium compound, and/or other precursors. The nucleophilic reagent may include, e.g., ethylene glycol ethers, such as glyme, diglyme, triglyme, tetraglyme, etc.; crown ethers, such as 18-crown-6, dicyclohexyl-18-crown-6,24-crown-8, dicyclohexyl-24-crown-8, dibenzo-24-crown-8, etc.; polyamines, such as ethylenediamine, N,N′-tetramethylethylenediamine, diethylenetriamine, triethylenetetramine, tetraethylenepentamine, pentaethylenehexamine, 1,1,4,7,7-pentamethyldiethylenetriamine, 1,1,4,7,10,10-hexamethyltriethylenetetramine, triethoxytriethyleneamine, etc.; cyclic polyamines, such as cyclam and cyclen, etc.; heterocyclic compounds, such as pyridine, pyrrolidine, piperidine, morpholine, N-methylpyrrolidine, N-methylpiperidine, N-methylmorpholine, tetrahydrofuran, tetrahydropyran, 1,4-dioxane, oxazole, thiazole, oxathiolane, etc.; β-ketone esters, such as methyl acetoacetate, ethyl acetoacetate, 2-methoxyethyl acetoacetate, etc.; or β-diketones, such as acetyl acetone, 2,4-hexanedione, 2,4-heptanedione, 3,5-heptanedione, dipivaloyl methane, etc. An amount of the nucleophilic reagent used may be in a range of about 0.1 mol to about 10 mol with respect to 1 mol of the total amount of precursor, e.g., in a range of about 1 mol to about 4 mol.

In a source material for forming an yttrium-containing film used to form an yttrium-containing film in the method of manufacturing an integrated circuit device, an amount of impurity may be maximally suppressed, such as halogen impurity, a metal element impurity, a chlorine impurity, or the like, and an organic impurity, as much as possible. In an implementation, in the source material for forming an yttrium-containing film, a metal element impurity may be included in an amount of about 100 ppb or less for each element. In an implementation, the metal element impurity may include about 10 ppb or less of metal element impurity for each element, and the total amount of the metal element impurity may be about 1 ppm or less, e.g., about 100 ppb or less. In an implementation, in the case of forming a thin film used as a gate insulating film, a gate conductive film, or a barrier film of a large scale integrated circuit (LSI), the content of alkali metal elements and alkaline earth metal elements affecting an electrical property of a resultant thin film may be reduced as low as possible. In an implementation, the halogen impurity in the source material for forming an yttrium-containing film may be about 100 ppm or less or, about 10 ppm or less, e.g., about 1 ppm or less.

The organic impurity that may be included in the source material for forming an yttrium-containing film may be about 500 ppm or less or, about 50 ppm or less, e.g., about 10 ppm or less, as a total amount of the organic impurity.

When moisture is included in the source material for forming an yttrium-containing film, it could generate particles in the source material or during thin film formation. Accordingly, precursors, organic solvents, and nucleophilic reagents may be dehydrated prior to use. The moisture content of each of the precursors, the organic solvent, and the nucleophilic reagent may be about 10 ppm or less, e.g., about 1 ppm or less.

In forming an yttrium-containing film in the method of manufacturing an integrated circuit device, in order to reduce particle contamination in the yttrium-containing film to be formed, the content of particles in the source material for forming an yttrium-containing film may be minimized. In an implementation, when measuring particles by a light scattering type particle detector in a liquid phase, the number of particles greater than 0.3 μm in the source material for forming an yttrium-containing film may be 100 or less in 1 ml of a liquid phase and the number of particles greater than 0.2 μm may be 1,000 or less in 1 ml of a liquid phase, e.g., the number of particles greater than 0.2 μm may be 100 or less in 1 ml of the liquid phase.

In order to form an yttrium-containing film using the source material for forming an yttrium-containing film in operation P20 of FIG. 1, operation P20 may include a process of forming a precursor thin film on the substrate by vaporizing the source material for forming an yttrium-containing film and introducing the vaporized source material into a deposition reaction unit where the substrate is located, and depositing the source material for forming the yttrium-containing film on a surface of the substrate, and a process of forming an yttrium-containing film including yttrium atoms (Y) on the surface of the substrate by reacting the precursor thin film with a reactive gas.

In order to vaporize the source material for forming an yttrium-containing film and introduce the vaporized source material to the deposition reaction unit, the above-described gas transportation method, liquid transportation method, single source method, cocktail source method, or the like may be used.

The reactive gas is a gas that reacts with the precursor thin film. In an implementation, the reactive gas may include an oxidizing gas, a reducing gas, or a nitriding gas.

The oxidizing gas may include, e.g., O₂, O₃, O₂ plasma, H₂O, NO₂, NO, N₂O (nitrous oxide), CO, CO₂, H₂O₂, HCOOH, CH₃COOH, (CH₃CO)₂O, alcohol, peroxide, sulfur oxide, or a combination thereof.

The reducing gas may include, e.g., a hydrocarbon compound, such as methane and ethane, hydrogen, carbon monoxide, an organometallic compound, or a combination thereof.

The nitriding gas may include, e.g., NH₃, N₂ plasma, monoalkylamine, dialkylamine, trialkylamine, an organic amine compound, such as alkylenediamine, hydrazine compound, or a combination thereof.

When an yttrium oxide film is formed as the yttrium-containing film in operation P20 of FIG. 1, the oxidizing gas may be used as the reactive gas. In the case of forming an yttrium nitride film in operation P20 of FIG. 1, the nitriding gas may be used as the reactive gas.

In an implementation, in order to form an yttrium-containing film including yttrium atoms (Y) in operation P20 of FIG. 1, a thermal CVD process for forming a thin film by reacting a source material gas containing the yttrium compound or the source material gas with a reactive gas only heat, a plasma CVD process using heat and plasma, an optical CVD process using heat and light, an optical plasma CVD process using heat and light and plasma, or an ALD process may be used.

In forming an yttrium-containing film according to operation P20 of FIG. 1, the reaction temperature (substrate temperature), reaction pressure, deposition rate, and the like may be appropriately selected according to the desired thickness and type of the yttrium-containing film. The reaction temperature may be in a range of room temperature to about 500° C., which is a temperature at which the source material for forming an yttrium-containing film may sufficiently react, e.g., in a range of about 200° C. to about 450° C. In an implementation, the reaction pressure may range from about 10 Pa to atmospheric pressure for a thermal CVD process or an optical CVD process, e.g., in a range from about 10 Pa to about 2,000 Pa when using plasma.

In forming an yttrium-containing film according to operation P20 of FIG. 1, when an ALD process is used, the thickness of the yttrium-containing film may be adjusted by adjusting the number of cycles of the ALD process. When an yttrium-containing film is formed on the substrate by using the ALD process, a source material gas introduction process of introducing a vapor formed by vaporizing a source material for forming an yttrium-containing film including the yttrium compound according to an embodiment into a deposition reaction unit (e.g., reactor); a precursor thin film forming process in which a precursor thin film is formed on a surface of the substrate by using the vapor; an exhaust process of exhausting unreacted source material gas remaining in a reaction space on the substrate; and a process of forming an yttrium-containing film on the substrate by causing a chemical reaction between the precursor thin film and a reactive gas.

In an implementation, the process of vaporizing the source material for forming an yttrium-containing film may be performed in a source material container or may be performed in a vaporization chamber. The process of vaporizing the source material for forming an yttrium-containing film may be performed in a range of about 0° C. to about 150° C. When the source material for forming an yttrium-containing film is vaporized, a pressure inside the source material container or the vaporization chamber may be in a range of about 1 Pa to about 10,000 Pa.

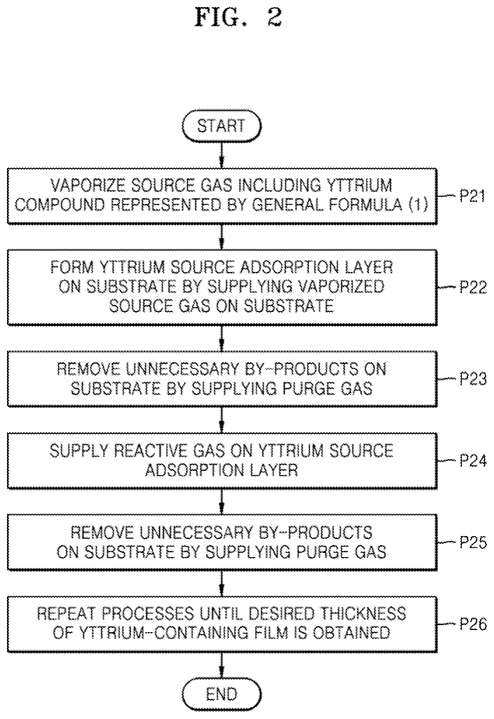

FIG. 2 is a flowchart specifically illustrating a method of forming an yttrium-containing layer.

Referring to FIG. 2, the method of forming an yttrium-containing film by using an ALD process according to operation P20 of FIG. 1 will be described in detail.

Referring to FIG. 2, in operation P21, a source gas including an yttrium compound having the structure of General Formula (1) may be vaporized.

In an implementation, the source gas may include the above-described source material for forming an yttrium-containing film. The process of vaporizing the source gas may be performed in a range of about 0° C. to about 150° C. When the source gas is vaporized, the pressure inside the source material container or the vaporization chamber may be in a range of about 1 Pa to about 10,000 Pa.

In operation P22, the source gas vaporized according to operation P21 may be supplied onto the substrate to form an yttrium source adsorption layer including yttrium atoms (Y) on the substrate. In an implementation, the substrate temperature may be in a range of room temperature to about 400° C., e.g., about 200° C. to about 400° C. When the process is performed, the pressure in a reaction space may be in a range from about 1 Pa to about 10,000 Pa, e.g., from about 10 Pa to about 1,000 Pa.

By supplying the vaporized source gas onto the substrate, an adsorption layer including a chemisorbed layer and a physisorbed layer of the vaporized source gas may be formed on the substrate. In an implementation, when the source material for forming an yttrium-containing film includes other precursors besides the yttrium compound, the other precursors are also deposited on a surface of the substrate together with the yttrium compound.

In operation P23, a purge gas may be supplied to the substrate to remove unnecessary by-products on the substrate.

The purge gas may include, e.g., an inert gas, such as Ar, He, or Ne, or N₂ gas.

In an implementation, instead of the purge process, the reaction space in which the substrate is located may be depressurized and exhausted. In an implementation, for the depressurization, the pressure of the reaction space may be in a range of about 0.01 Pa to about 300 Pa, e.g. about 0.01 Pa to about 100 Pa.

In an implementation, a process of heating the substrate on which the yttrium source adsorption layer including the yttrium atom (Y) is formed or heat-treating the reaction chamber in which the substrate is accommodated may further be performed.

In operation P24, a reactive gas may be supplied onto the yttrium source adsorption layer formed on the substrate to form an yttrium-containing film in an atomic layer unit.

In an implementation, when forming an yttrium oxide film on the substrate, the reactive gas may include O₂, O₃, O₂ plasma, H₂O, NO₂, NO, N₂O (nitrous oxide), CO, CO₂, H₂O₂, HCOOH, CH₃COOH, (CH₃CO)₂O, or a combination thereof.

The reaction space may be in a range of room temperature to about 500° C., e.g., about 200° C. to about 400° C., so that the yttrium source adsorption layer and the reactive gas may sufficiently react while operation P24 is performed. The pressure in the reaction space during the operation P24 may be in a range of about 1 Pa to about 10,000 Pa, e.g., in a range of about 10 Pa to about 1,000 Pa.

During the operation P24, the reactive gas may be plasma-treated. A high radio frequency (RF) output during the plasma treatment may be in a range of about 0 W to about 1,500 W, e.g., about 50 W to about 600 W.

In operation P25, a purge gas may be supplied on the substrate to remove unnecessary by-products on the substrate.

The purge gas may include, e.g., an inert gas, such as Ar, He, or Ne, or N₂ gas.

In operation P26, operations P21 to P25 of FIG. 2 may be repeated until an yttrium-containing film having a desired thickness is formed.

A thin film deposition process including a series of operations including operations P21 to P25 may be set as one cycle, and the cycle may be repeated a plurality of times until an yttrium-containing film having a desired thickness is formed. In an implementation, after performing one cycle, an exhaust process using a purge gas may be performed similarly to the operation P23 or operation P25 to exhaust unreacted gases from the reaction chamber, and then the subsequent cycle may be performed.

In an implementation, in order to control a deposition rate of the yttrium-containing film, a source material supply condition (e.g., a vaporization temperature or vaporization pressure of a source material), a reaction temperature, a reaction pressure, or the like may be controlled. If the deposition rate of the yttrium-containing film were to be too high, properties of the obtained yttrium-containing film could deteriorate, and if the deposition rate of the yttrium-containing film were to be too low, productivity could be reduced. The deposition rate of the yttrium-containing film may be in a range from about 0.01 nm/min to about 100 nm/min, e.g., about 1 nm/min to about 50 nm/min. When the yttrium-containing film is formed using an ALD process, the number of ALD cycles may be adjusted in order to control the yttrium-containing film having a desired thickness.

In an implementation, in order to form an yttrium-containing film on the substrate, the yttrium compound having the structure of the General formula (1) may be supplied with at least one of another precursor, a reactive gas, a carrier gas, and a purge gas, or sequentially on the substrate. More detailed configurations of the other precursor, the reactive gas, the carrier gas, and the purge gas that may be supplied on the substrate together with the yttrium compound having the structure of the General formula (1) are as described above.

In an implementation, in the process of forming the yttrium-containing film described with reference to FIG. 2, a reactive gas may be supplied on the substrate between processes P21 to P25, respectively.

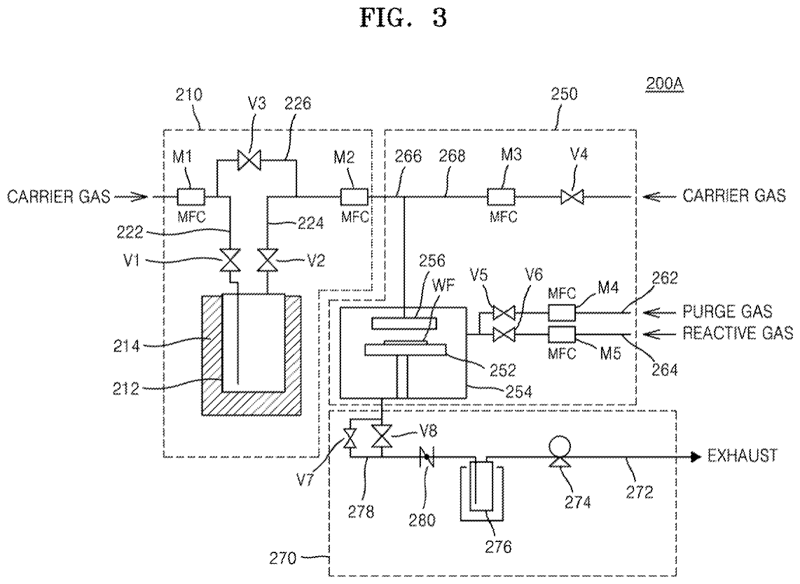

FIGS. 3 to 6 are schematic diagrams each schematically illustrating a configuration of a deposition apparatus 200A, 200B, 200C, and 200D that may be used in a process of forming an yttrium-containing film in a method of manufacturing an integrated circuit device, according to an embodiment.

Referring to FIGS. 3 to 6, each of the deposition apparatuses 200A, 200B, 200C, and 200D may include a fluid transfer unit 210, a thin film forming unit 250 in which a deposition process for forming a thin film on the substrate WF is performed using a process gas supplied from a source material container 212 in the fluid transfer unit 210; and an exhaust system 270 for discharging remaining gas or reaction by-products used in the reaction in the thin film forming unit 250.

The thin film forming unit 250 may include a reaction chamber 254 having a susceptor 252 that supports the substrate WF. A shower head 256 for supplying a gas supplied from the fluid transfer unit 210 onto the substrate WF may be installed at an upper end of the reaction chamber 254.

The fluid transfer unit 210 may include an inlet line 222 for supplying a carrier gas from the outside to the source material container 212, and an outlet line 224 for supplying a source material compound accommodated in the source material container 212 to the thin film forming unit 250. Valves V1 and V2 and mass flow controllers (MFCs) M1 and M2 may be installed in the inlet line 222 and the outlet line 224, respectively. The inlet line 222 and the outlet line 224 may be interconnected via a bypass line 226. A valve V3 may be installed on the bypass line 226. The valve V3 may be pneumatically actuated by an electric motor or other remotely controllable means.

The source material compound supplied from the source material container 212 may be supplied to the reaction chamber 254 through an inlet line 266 of the thin film forming unit 250 connected to the outlet line 224 of the fluid transfer unit 210. In an implementation, the source material compound supplied from the source material container 212 may be supplied into the reaction chamber 254 together with a carrier gas supplied through an inlet line 268. A valve V4 and an MFC M3 may be installed in the inlet line 268 through which the carrier gas is introduced.

The thin film forming unit 250 may include an inlet line 262 for supplying a purge gas and an inlet line 264 for supplying a reactive gas into the reaction chamber 254. Valves V5 and V6 and MFCs M4 and M5 may be installed in the inlet lines 262 and 264, respectively.

A process gas used in the reaction chamber 254 and reaction by-products for disposal may be discharged to the outside through the exhaust system 270. The exhaust system 270 may include an exhaust line 272 connected to the reaction chamber 254, and a vacuum pump 274 installed in the exhaust line 272. The vacuum pump 274 may remove the process gas discharged from the reaction chamber 254 and reaction by-products for disposal.

In the exhaust line 272, a trap 276 may be installed at an upstream side of the vacuum pump 274. The trap 276 may trap, e.g., reaction by-products generated by the process gas that has not fully reacted within the reaction chamber 254 so that the reaction by-products do not flow into the vacuum pump 274 on the downstream side of the trap 276.

The trap 276 installed in the exhaust line 272 may trap deposits, such as reaction by-products generated by a reaction between the process gases so as not to flow to the downstream side of the trap 276. The trap 276 may have a configuration that may be cooled by a cooler or water cooling.

In an implementation, a bypass line 278 and an automatic pressure controller 280 may be installed at an upstream side of the trap 276 in the exhaust line 272. Valves V7 and V8 may be installed on the bypass line 278 and on a portion of the exhaust line 272 extending in parallel to the bypass line 278, respectively.

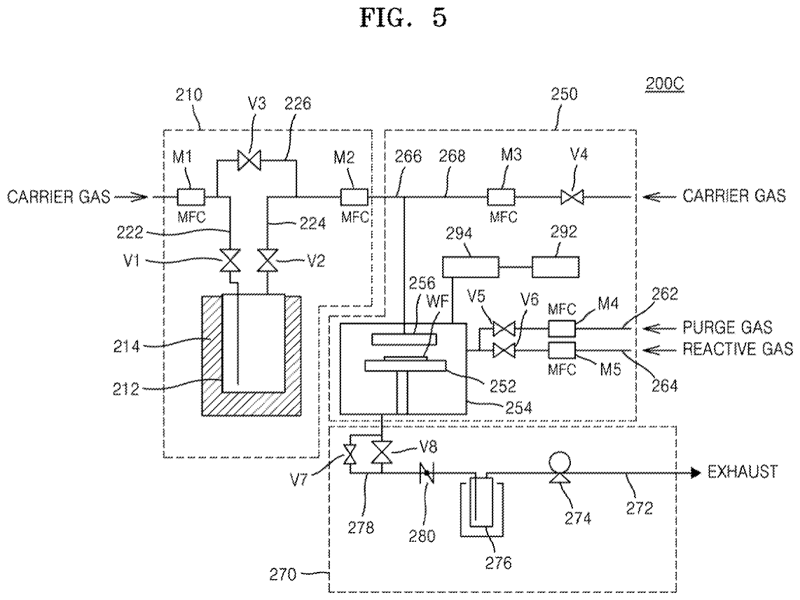

As in the deposition apparatuses 200A and 200C illustrated in FIGS. 3 and 5, a heater 214 may be installed in the source material container 212. The temperature of the source material compound accommodated in the source material container 212 may be maintained at a relatively high temperature by the heater 214.

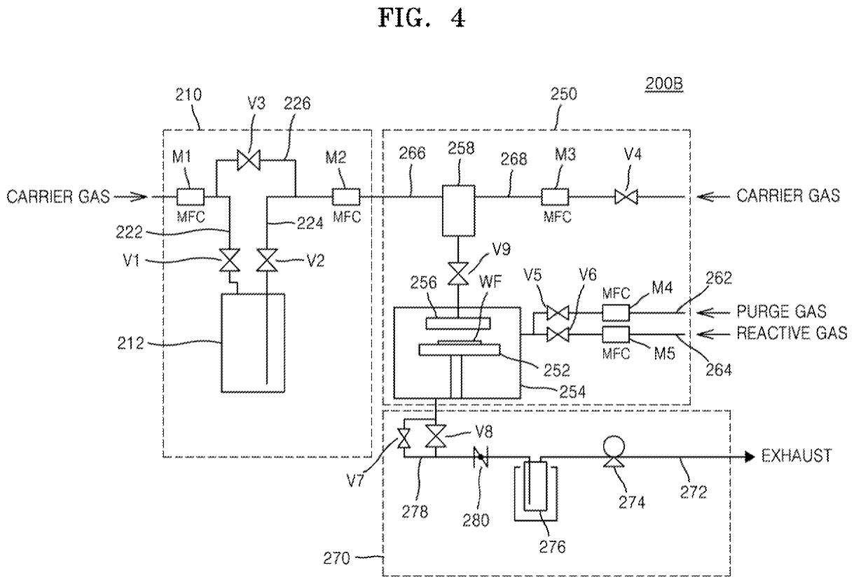

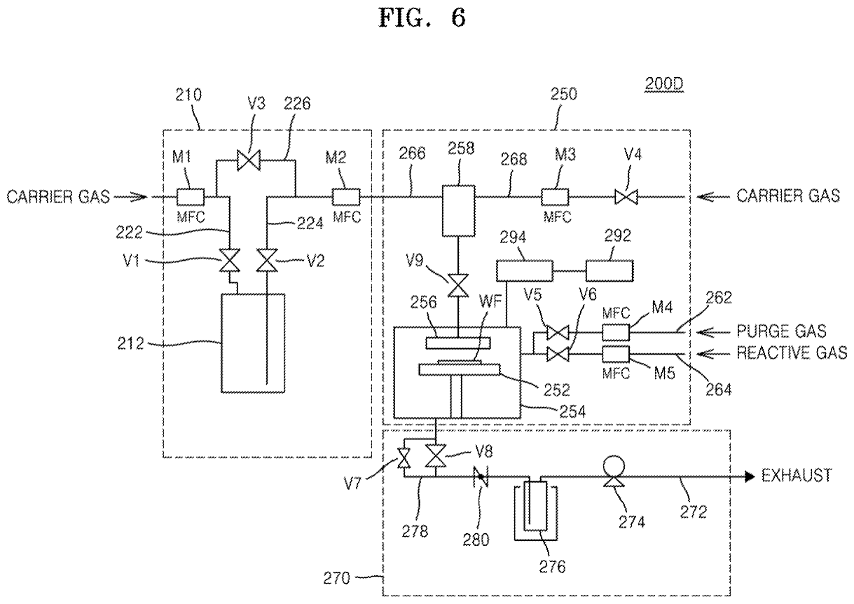

As in the deposition apparatuses 200B and 200D illustrated in FIGS. 4 and 6, a vaporizer 258 may be installed in the inlet line 266 of the thin film forming unit 250. The vaporizer 258 may vaporize a fluid supplied in a liquid state from the fluid transfer unit 210 and supplies the vaporized source material into the reaction chamber 254. The source material compound vaporized in the vaporizer 258 may be supplied into the reaction chamber 254 together with a carrier gas supplied through the inlet line 268. The inflow of the source material compound supplied to the reaction chamber 254 through the vaporizer 258 may be controlled by the valve V9.

In an implementation, as in the deposition apparatuses 200C and 200D illustrated in FIGS. 5 and 6, the thin film forming unit 250 may include a high-frequency power source 292 and an RF matching system 294 connected to the reaction chamber 254 to generate plasma in the reaction chamber 254.

In an implementation, as illustrated in FIGS. 3 to 6, the deposition apparatuses 200A, 200B, 200C, and 200D may have a configuration in which one source material container 212 is connected to the reaction chamber 254. In an implementation, a plurality of source material containers 212 may be provided in the fluid transfer unit 210, and the plurality of source material containers 212 may be respectively connected to the reaction chamber 254. The number of source material containers 212 connected to the reaction chamber 254 may be a suitable number.

In an implementation, in order to vaporize a source material for forming an yttrium-containing film including the yttrium compound of the General formula (1), the vaporizer 258 installed in any one of the deposition apparatuses 200B and 200D illustrated in FIGS. 4 and 6 may be used.

In order to form an yttrium-containing film on the substrate according to the method of manufacturing the integrated circuit device described with reference to FIGS. 1 and 2, any one of the deposition apparatuses 200A, 200B, 200C, and 200D illustrated in FIGS. 3 to 6 may be used. In an implementation, the yttrium compound according to an embodiment having the structure of the General formula (1) may be transported through various methods and supplied to a reaction space of a thin film forming apparatus, e.g., the reaction chamber 254 of the deposition apparatuses 200A, 200B, 200C, and 200D illustrated in FIGS. 3 to 6.

In an implementation, yttrium-containing films may be simultaneously formed on a plurality of substrates by using a batch-type facility other than wafer type facility such as, the deposition apparatuses 200A, 200B, 200C, and 200D illustrated in FIGS. 3 to 6 for forming an yttrium-containing film according to the method described with reference to FIGS. 1 and 2.

In forming an yttrium-containing film in the method of manufacturing an integrated circuit device, a reaction temperature (substrate temperature), reaction pressure, deposition rate, etc. may be mentioned as conditions for forming the yttrium-containing film.

The reaction temperature is a temperature at which the yttrium compound, e.g., the yttrium compound having the structure of the General formula (1) may sufficiently react, may be in a range of room temperature to about 500° C., e.g., about 200° C. to about 450° C. In an implementation, the reaction pressure may be in a range from about 10 Pa to atmospheric pressure for a thermal CVD process or an optical CVD process, e.g., about 10 Pa to about 2,000 Pa when using plasma.

In an implementation, the deposition rate may be controlled by adjusting supply conditions (e.g., vaporization temperature and vaporization pressure), reaction temperature, and reaction pressure of the source material compound. In the method of forming a thin film, the deposition rate of the yttrium-containing film may be in a range from about 0.01 nm/min to about 100 nm/min, e.g., about 1 nm/min to about 50 nm/min. When the yttrium-containing film is formed by using an ALD process, the number of ALD cycles may be adjusted in order to control the thickness of the yttrium-containing film.

In an implementation, when the yttrium-containing layer is formed using the ALD process, energy, such as plasma, light, voltage, etc. may be applied. A time point for applying the energy may be variously selected. In an implementation, energy, such as plasma, light, voltage, etc. may be applied when introducing a source gas including an yttrium compound into the reaction chamber, adsorbing the source gas onto the substrate, performing an exhaust process using a purge gas, introducing a reactive gas into the reaction chamber, or between the respective time points.

In an implementation, after forming an yttrium-containing film using the yttrium compound having the structure of the General formula (1), annealing under an inert atmosphere, an oxidizing atmosphere, or a reducing atmosphere may be further performed. In an implementation, in order to bury a step formed on a surface of the yttrium-containing film, a reflow process may be performed on the yttrium-containing film. The annealing process and the reflow process may each be performed in a temperature range of about 200° C. to about 1,000° C., e.g., about 250° C. to about 500° C.

In an implementation, various types of yttrium-containing films may be formed by appropriately selecting an yttrium compound, other precursors used with the yttrium compound, a reactive gas, and process conditions forming an yttrium-containing film. In an implementation, an yttrium-containing film formed may be an yttrium oxide film or an yttrium-containing composite oxide film.

The yttrium-containing film according to an embodiment may be used as a material for various components constituting an integrated circuit device. In an implementation, electrode materials for dynamic random-access memory (DRAM) devices, gates and resistors of transistors, diamagnetic films for hard disk recording layers, catalyst materials for solid polymer fuel cells, conductive barrier films for metal wiring, capacitors of a dielectric film, a barrier metal film for liquid crystal, a member for a thin film solar cell, a member for a semiconductor equipment, nano structures, etc.

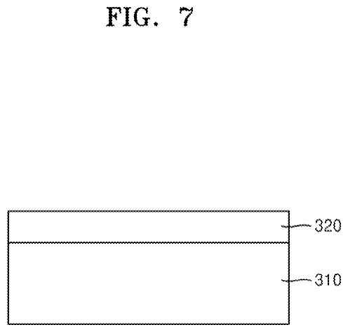

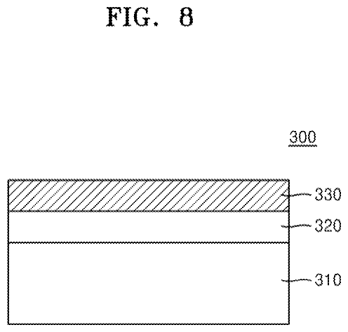

FIGS. 7 and 8 are cross-sectional views of stages in a method of manufacturing an integrated circuit device 300 according to an embodiment.

Referring to FIG. 7, a lower structure 320 may be formed on a substrate 310.

The substrate 310 may include a semiconductor, such as Si or Ge, or a compound semiconductor, such as SiGe, SiC, GaAs, InAs, or InP. The substrate 310 may include a conductive region, e.g., a well doped with an impurity or a structure doped with an impurity.

In an implementation, the lower structure 320 may include a conductive film. In an implementation, the lower structure 320 may include a doped semiconductor, a conductive metal nitride, a metal, a metal silicide, a conductive oxide, or a combination thereof In an implementation, the lower structure 320 may include NbN, TiN, TiAlN, TaN, TaAlN, W, WN, Ru, RuO₂, SrRuO₃, Ir, IrO₂, Pt, PtO, SRO(SrRuO₃), BSRO((Ba,Sr)RuO₃), CRO(CaRuO₃), LSCo((La,Sr)CoO₃), or a combination thereof. In order to form the lower structure 320, a CVD, metal organic CVD (MOCVD), or ALD process may be used.

In an implementation, the lower structure 320 may include an insulating layer. In an implementation, the lower structure 320 may include oxides, such as boro phospho silicate glass (BPSG), phospho silicate glass (PSG), or undoped silicate glass (USG), silicon oxide, silicon nitride, silicon carbonitride, silicon oxycarbonitride, titanium oxide, tantalum oxide, or a combination thereof.

In an implementation, the lower structure 320 may include a dielectric layer. In an implementation, the lower structure 320 may include hafnium oxide, hafnium oxynitride, hafnium silicon oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, or a combination thereof.

Referring to FIG. 8, an yttrium-containing film 330 may be formed on the lower structure 320. The yttrium-containing film 330 may be formed to be in contact (e.g., direct contact) with the lower structure 320.

In order to form the yttrium-containing film 330, an yttrium compound represented by the General formula (1) may be used. In an implementation, in order to form the yttrium-containing film 330, the processes described with reference to FIG. 1 or 2 may be performed.

In the method of manufacturing the integrated circuit device 300 described with reference to FIGS. 7 and 8, the lower structure 320 may have a three-dimensional structure having a relatively large aspect ratio. An ALD process may be used to form the high-quality yttrium-containing film 330 in a deep and narrow three-dimensional space on the lower structure 320.

In the method of manufacturing the integrated circuit device 300 described with reference to FIGS. 7 and 8, in forming the yttrium-containing film 330, process stability may be improved by using the yttrium compound of the General formula (1).

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

Next, specific examples of synthesizing the yttrium compound and methods of forming an yttrium-containing film according to embodiments will be described.

### Synthesis Example 1 (Synthesis of the Compound of Chemical Formula 23)

In a 100 ml flask purged with Ar, 1.50 g (2.63×10⁻³ mol) of tris[N,N-bis(trimethylsilyl)amide]yttrium was added to 14 ml of a toluene solvent to form a mixture and the mixture was cooled. Then, after slowly adding 0.530 g (2.66×10⁻³ mol) of N-(tert-butyl)-N′-(1-dimethylamino)propan-2-yl) acetamidinate thereto, the temperature was raised to room temperature, and the mixture was stirred for one day. After cooling the mixture, 1.26 g (5.32×10⁻³ mol) of nonafluoro-tert-butyl alcohol was added, and the mixture was stirred for one day. After removing the solvent from the obtained resultant product at an oil bath temperature of 70° C. under a reduced pressure, 0.8 g (yield 40%) of the compound of Chemical Formula 23 was obtained by performing distillation purification at an oil bath temperature of 140° C. and the degree of vacuum of 30 Pa.
(1) Elemental Analysis (Metal Analysis: ICP-AES)
(Analysis value) C: 30.10, H: 3.15, F: 45.19, N: 5.59, O: 4.26, Y: 11.71
(Theoretical value) C: 30.13, H: 3.19, F: 45.16, N: 5.55, O: 4.23, Y: 11.74
(2) Analysis result by ¹H-NMR (heavy benzene)
2.72 ppm (1 H, multiplet), 2.09 ppm (1 H, multiplet), 2.05 ppm (3 H, singlet), 1.66 ppm (3 H, singlet), 1.49 ppm (3 H, singlet), 1.43 ppm (1 H, multiplet), 1.15 ppm (9 H, singlet), 0.60 ppm (3 H, doublet)

### Synthesis Example 2 (Synthesis of the Compound of Chemical Formula 59)

In a 100 ml flask purged with Ar, 1.50 g (2.63×10⁻³ mol) of tris[N,N-bis(trimethylsilyl)amide]yttrium was added to 14 ml of a toluene solvent to form a mixture and the mixture was cooled. Then, after slowly adding 0.61 g (2.66×10⁻³ mol) of (E)-N,N′-bis(1-methoxybutan-2-yl)acetamidinate to the mixture, the temperature was raised to room temperature, and the mixture was stirred for 8 hours. After cooling the mixture, 1.26 g (5.32×10⁻³ mol) of nonafluoro-tert-butyl alcohol was added, the temperature was raised to room temperature, and the mixture was stirred for 8 hours. After removing the solvent from the obtained resultant product at an oil bath temperature of 70° C. under reduced pressure, 0.9 g (yield 44%) of a compound of Chemical Formula 59 was obtained by performing distillation purification at an oil bath temperature of 130° C. and the degree of vacuum of 30 Pa.
(1) Elemental Analysis (Metal Analysis: ICP-AES)
(Analysis value) C: 30.40, H: 3.23, F: 43.42, N: 3.51, O: 8.14, Y: 11.30
(Theoretical) C: 30.47, H: 3.20, F: 43.38, N: 3.55, O: 8.12, Y: 11.28
(2) Analysis result by ¹H-NMR (heavy benzene)
3.26 ppm (6 H, singlet), 3.10 ppm (1 H, singlet), 1.44 ppm (3 H, singlet), 1.26 ppm (4 H, multiplet), 0.63 ppm (4 H, doublet), 0.49 ppm (6 H, triplet)

### Synthesis Example 3 (Synthesis of the Compound of Chemical Formula 64)

In a 100 ml flask purged with Ar, 1.50 g (2.63×10⁻³ mol) of tris[N,N-bis(trimethylsilyl)amide]yttrium was added to 14 ml of a toluene solvent to form a mixture and the mixture was cooled. The, after slowly adding 0.42 g (2.66×10⁻³ mol) of 3,3′-iminobis(N,N-dimethylethylamine) to the mixture, the temperature was raised to room temperature, and the mixture was stirred for 8 hours. After cooling the mixture, 1.26 g (5.32×10⁻³ mol) of nonafluoro-tert-butyl alcohol was added, the temperature was raised to room temperature, and the mixture was stirred for 8 hours. After removing the solvent from the obtained resultant product at an oil bath temperature of 70° C. under reduced pressure, 1.1 g of a compound of Chemical Formula 64 (yield 59%) was obtained by performing distillation purification at an oil bath temperature of 130° C. and the degree of vacuum of 30 Pa.
(1) Elemental Analysis (Metal Analysis: ICP-AES)
(Analysis value) C: 26.82, H: 2.78, F: 47.66, N: 5.89, 0: 4.42, Y: 12.44
(Theoretical) C: 26.79, H: 2.81, F: 47.68, N: 5.86, O: 4.46, Y: 12.40
(2) Analysis result by ¹H-NMR (heavy benzene)
2.68 ppm (4 H, triplet), 2.30 ppm (4 H, triplet), 1.99 ppm (12 H, singlet)

### Synthesis Example 4 (Synthesis of the Compound of Chemical Formula 67)

In a 100 ml flask purged with Ar, 1.50 g (2.63×10⁻³ mol) of tris[N,N-bis(trimethylsilyl)amide]yttrium was added to 14 ml of a toluene solvent to form a mixture and the mixture was cooled. Then, after slowly adding 0.50 g (2.66×10⁻³ mol) of 3,3′-iminobis(N,N-dimethylpropylamine) to the mixture, the temperature was raised to room temperature, and the mixture was stirred for 8 hours. After cooling the mixture, 1.26 g (5.32×10⁻³ mol) of nonafluoro-tert-butyl alcohol was added, the temperature was raised to room temperature, and the mixture was stirred for 8 hours. After removing the solvent from the obtained resultant product at an oil bath temperature of 70° C. under reduced pressure, 1.3 g of a compound of Chemical Formula 67 (yield 66%) was obtained by performing distillation purification at an oil bath temperature of 130° C. and the degree of vacuum of 30 Pa.
(1) Elemental Analysis (Metal Analysis: ICP-AES)
(Analysis value) C: 29.05, H: 3.21, F: 45.84, N: 5.60, O: 4.33, Y: 11.97
(Theoretical) C: 29.01, H: 3.25, F: 45.88, N: 5.64, O: 4.29, Y: 11.93
(2) Analysis result by 1H-NMR (heavy benzene)
2.69 ppm (4 H, triplet), 2.17 ppm (4 H, triplet), 2.08 ppm (12 H, singlet), 1.69 ppm (4 H, multiplet)

### Evaluation Examples and Comparative Evaluation Examples of Compounds

Each of the compounds of Chemical Formulas 23, 59, 64, and 67 obtained in Synthesis Examples 1 to 4 and Comparative Compounds 1 and 2 shown below were evaluated as follows.

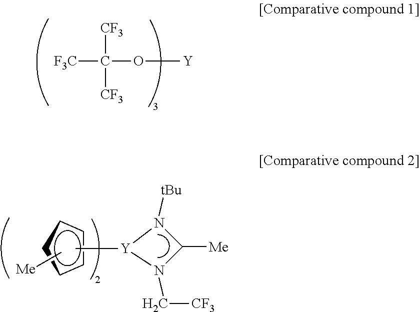

### (1) Temperature at 50 wt % Reduction in Atmospheric Pressure TG-DTA

The temperature (° C.) at which the weight of the compound to be evaluated decreased by 50 wt % was evaluated as “the temperature when the atmospheric pressure TG-DTA decreases by 50 wt %” by measuring atmospheric pressure, an Ar flow rate (100 ml/min), a temperature increase rate (10° C./min), and a scanning temperature range (30° C. to 600° C.) using TG-DTA. A compound having a low temperature when the atmospheric pressure TG-DTA is reduced by 50 wt % has a high vapor pressure and may be determined to be suitable as a source material for forming a thin film. The results are shown in Table 1.

### (2) Thermal Stability Evaluation

The thermal decomposition initiation temperature was measured using a differential scanning calorimetry (DSC) measuring device. A compound having a relatively high thermal decomposition initiation temperature is not easily thermally decomposed and may be determined to be suitable as a source material for forming a thin film. The results are shown in Table 1.

TABLE 1

| | | Atmospheric | |
|---|---|---|---|
| | | pressure | Thermal |
| | | TG-DTA | decomposition |
| | | Temperature | start |
| | | at 50 wt % | temperature |
| | Compound | decrease [° C.] | [° C.] |
| Evaluation Example 1 | Chemical | 205 | 330 |
| | Formula 23 | | |
| Evaluation Example 2 | Chemical | 210 | 275 |
| | Formula 59 | | |
| Evaluation Example 3 | Chemical | 190 | 300 |
| | Formula 64 | | |
| Evaluation Example 4 | Chemical | 210 | 305 |
| | Formula 67 | | |
| Comparative evaluation | Comparative | 205 | 225 |
| example 1 | compound 1 | | |
| Comparative evaluation | Comparative | 255 | 255 |
| example 2 | compound 2 | | |

From the results of Table 1, it may be seen that the compounds of Chemical Formula 23, Chemical Formula 59, Chemical Formula 64, and Chemical Formula 67, which are yttrium compounds according to an embodiment, had a higher vapor pressure than Comparative Compound 2.

In addition, it may be seen that the compounds of Chemical Formulas 23, 59, 64, and 67 had a thermal decomposition initiation temperature of 20° C. or greater than those of Comparative Compound 1 and Comparative Compound 2. It may be seen that the compounds of Chemical Formulas 23, 64, and 67 had a thermal decomposition initiation temperature of 45° C. or greater than those of Comparative Compound 1 and Comparative Compound 2. It may be that the compound of Chemical Formula 23 had a thermal decomposition initiation temperature of 75° C. or more greater than Comparative Compound 1 and Comparative Compound 2.

### Evaluation Examples of Thin Film Formation

An yttrium-containing film was formed on a substrate by an ALD process using the deposition apparatus of FIG. 3 using the compounds of Chemical Formulas 23, 59, 64, and 67 obtained in Synthesis Examples 1 to 4, and Comparative Compound 1 and Comparative Compound 2, respectively, as source materials.

Conditions for the ALD process for forming the yttrium-containing film were as follows.

### [Condition]

Reaction temperature (substrate temperature): 350° C.
Reactive Gas: O₃

### [Process]

Under the above conditions, the following series of processes (1) to (4) were used as one cycle, and 50 cycles were repeated.

Process (1): A process of introducing a vaporized source material into the chamber under the conditions of a source material container heating temperature of 150° C. and a source material container internal pressure of 100 Pa, and depositing it for 20 seconds at a pressure of 100 Pa in the chamber.

Process (2): A process of removing unreacted source materials by Ar purge for 15 seconds.

Process (3): A process of supplying a reactive gas and reacting at a chamber pressure of 100 Pa for 0.4 seconds.

Process (4): A process of removing unreacted source materials by Ar purge for 90 seconds.

The thickness of each of the thin films obtained in the above process was measured by an X-ray reflectance method, the compounds of the obtained thin films were confirmed by the X-ray diffraction method, and the carbon content of each of the obtained thin films was measured by X-ray photoelectron spectroscopy, and the result is shown in Table 2.

TABLE 2

| | | thickness | compound | carbon |
|---|---|---|---|---|
| | compound | of thin film | of thin film | content |
| Evaluation | Chemical | 5.5 nm | yttrium oxide | Not |
| Example 5 | Formula 23 | | | detected^{※1} |
| Evaluation | Chemical | 4.0 nm | yttrium oxide | Not |
| Example 6 | Formula 59 | | | detected^{※1} |
| Evaluation | Chemical | 5.5 nm | yttrium oxide | Not |
| Example 7 | Formula 64 | | | detected^{※1} |
| Evaluation | Chemical | 4.5 nm | yttrium oxide | Not |
| Example 8 | Formula 67 | | | detected^{※1} |
| Comparative | Comparative | 3.0 nm | yttrium oxide | 7 atm % |
| evaluation | compound 1 | | | |
| example 3 | | | | |
| Comparative | Comparative | 2.0 nm | yttrium oxide | 5 atm % |
| evaluation | compound 2 | | | |
| example 4 | | | | |

^{※1}Detection limit is 0.1 atm %

From the results of Table 2, among the yttrium oxide thin films obtained by the ALD process, the thin films obtained from Comparative Compound 1 and Comparative Compound 2 each had a carbon content of 5 atm % or more. On the other hand, the thin films obtained from the compounds of Chemical Formulas 23, 59, 64, and 67 obtained in Synthesis Examples 1 to 4 had a carbon content below the detection limit of 0.1 atm %, and thus, it may be seen that the thin films were high-quality yttrium oxide thin films.

In addition, as a result of evaluating the thickness of the yttrium oxide thin films obtained after 50 cycles of the ALD process, the thicknesses of the yttrium oxide thin films obtained from Comparative Compound 1 and Comparative Compound 2 were each less than 3.0 nm. On the other hand, the yttrium oxide thin films obtained from the compounds of Chemical Formulas 23, 59, 64, and 67 obtained in Synthesis Examples 1 to 4 were 4.0 nm or more, and thus, it may be seen that the productivity of the thin film formation process was excellent. The yttrium oxide thin films obtained from the compounds of Chemical Formulas 23 and 64 were 5.5 nm or more, and thus, it may be seen that the productivity of the thin film formation process was particularly excellent.

As observed from the above Evaluation Examples, the yttrium compounds according to an embodiment had a relatively high vapor pressure, and when used as a source material for forming a thin film by using an ALD or CVD process, it is possible to increase the productivity of the thin film formation.

By way of summation and review, when forming an yttrium-containing film required for manufacturing an integrated circuit device, a source material compound may provide excellent burial properties and excellent step coverage characteristics, and may be advantageous in terms of process stability and mass productivity due to easy handling.

By forming an yttrium-containing film using an yttrium compound according to the embodiments, a method of manufacturing an integrated circuit device capable of improving electrical characteristics and product productivity may be provided.

One or more embodiments may provide an yttrium compound used for forming an yttrium-containing film.

One or more embodiments may provide an yttrium compound having properties suitable for use as a source material compound for forming an yttrium-containing film.

One or more embodiments may provide a method of manufacturing an integrated circuit device that provides desired electrical properties by forming an yttrium-containing film having excellent quality using an yttrium compound capable of providing excellent process stability and mass productivity.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An yttrium compound represented by the following General formula (1): 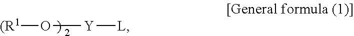
wherein, in General formula (1),
R¹ is an unsubstituted C1-C8 straight-chain or branched alkyl group or a fluorine-substituted C1-C8 straight-chain or branched alkyl group, and
L is a group represented by General formula (L-1) or General formula (L-2), 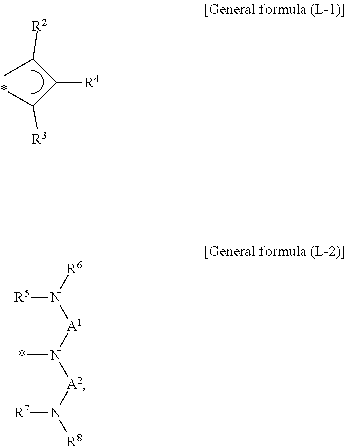
wherein, in General formula (L-1),
R² and R³ are each independently a substituted or unsubstituted C1-C8 straight-chain or branched alkyl group or a group represented by General formula (L-3) or General formula (L-4),
R⁴ is a hydrogen atom (H) or a substituted or unsubstituted C1-C5 straight-chain or branched alkyl group, and
* indicates a bonding position,
wherein, in General formula (L-2),
R⁵, R⁶, R⁷, and R⁸ are each independently a substituted or unsubstituted C1-C5 straight-chain or branched alkyl group,
A¹ and A² are each independently a substituted or unsubstituted C1-C5 alkanediyl group, and
* indicates a bonding position, 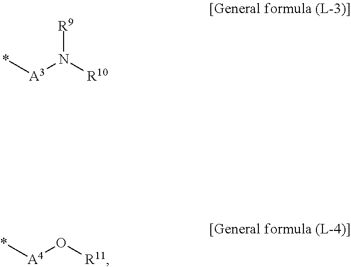
wherein, in General formulas (L-3) and (L-4),
R⁹, R¹⁰, and R¹¹ are each independently a substituted or unsubstituted C1-C5 straight-chain or branched alkyl group,
A³ and A⁴ are each independently a substituted or unsubstituted C1-C8 alkanediyl group, and
* indicates a binding position.

2. The yttrium compound as claimed in claim 1, wherein R¹ is a C2-C5 fluoroalkyl group.

3. The yttrium compound as claimed in claim 1, wherein:
L is a group represented by General formula (L-1), and
R² is a substituted or unsubstituted C3-C5 branched alkyl group.

4. The yttrium compound as claimed in claim 1, wherein:
L is a group represented by General formula (L-1), and
R³ is a group represented by General formula (L-3).

5. The yttrium compound as claimed in claim 1, wherein:
L is a group represented by General formula (L-1), and
R⁴ is a substituted or unsubstituted methyl group or a substituted or unsubstituted ethyl group.

6. The yttrium compound as claimed in claim 1, wherein:
L is a group represented by General formula (L-2), and
R⁵, R⁶, R⁷, and R⁸ are each independently a substituted or unsubstituted methyl group or a substituted or unsubstituted ethyl group.

7. The yttrium compound as claimed in claim 1, wherein:
L is a group represented by General formula (L-2), and
A¹ and A² are each independently a substituted or unsubstituted ethylene group or a substituted or unsubstituted propane-1,3-diyl group.

8. The yttrium compound as claimed in claim 1, wherein:
L is a group represented by General formula (L-1),
R² and R³ are each independently a group represented by General formula (L-3) or General formula (L-4), and
R⁹, R¹⁰, and R¹¹ are each independently a substituted or unsubstituted methyl group or a substituted or unsubstituted ethyl group.

9. The yttrium compound as claimed in claim 1, wherein:
L is a group represented by General formula (L-1),
R² and R³ are each independently a group represented by General formula (L-3) or General formula (L-4), and
A³ and A⁴ are each independently a substituted or unsubstituted C3-C4 alkanediyl group.

10. The yttrium compound as claimed in claim 1, wherein the yttrium compound is represented by the following General formula (2):

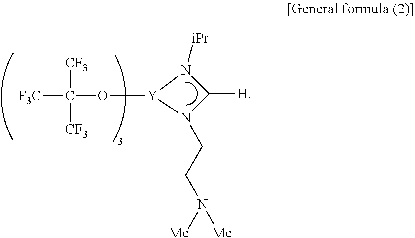

11. A method of manufacturing an integrated circuit device, the method comprising forming an yttrium-containing film on a substrate using an yttrium compound represented by General formula (1): 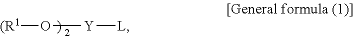
wherein, in General formula (1),
R¹ is an unsubstituted C1-C8 straight-chain or branched alkyl group or a fluorine-substituted C1-C8 straight-chain or branched alkyl group, and
L is a group represented by General formula (L-1) or General formula (L-2), 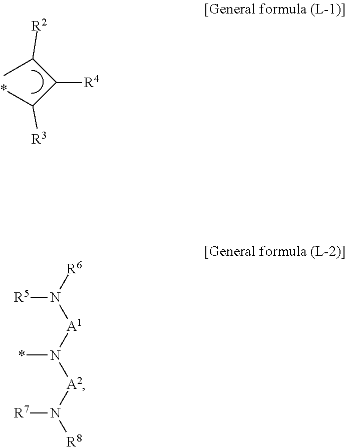
wherein, in General formula (L-1),
R² and R³ are each independently a substituted or unsubstituted C1-C8 straight-chain or branched alkyl group or a group represented by General formula (L-3) or General formula (L-4),
R⁴ is a hydrogen atom (H) or a substituted or unsubstituted C1-C5 straight-chain or branched alkyl group, and
* indicates a bonding position,
wherein, in General formula (L-2),
R⁵, R⁶, R⁷, and R⁸ are each independently a substituted or unsubstituted C1-C5 straight-chain or branched alkyl group,
A¹ and A² are each independently a substituted or unsubstituted C1-C5 alkanediyl group, and
* indicates a bonding position, 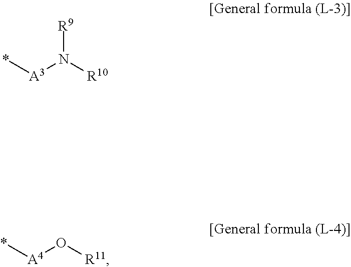
wherein, in General formulas (L-3) and (L-4),
R⁹, R¹⁰, and R¹¹ are each independently a substituted or unsubstituted C1-C5 straight-chain or branched alkyl group,
A³ and A⁴ are each independently a substituted or unsubstituted C1-C8 alkanediyl group, and
* indicates a binding position.

12. The method as claimed in claim 11, wherein forming the yttrium-containing film includes:
vaporizing the yttrium compound represented by General formula (1);
supplying the vaporized yttrium compound onto the substrate to form an yttrium source adsorption layer on the substrate; and
supplying a reactive gas on the yttrium source adsorption layer.

13. The method as claimed in claim 12, wherein:
the reactive gas includes an oxidizing gas, and
forming the yttrium-containing film includes forming an yttrium oxide film.

14. The method as claimed in claim 11, further comprising forming a lower structure on the substrate before forming the yttrium-containing film,
wherein:
the yttrium-containing film is formed in contact with the lower structure, and
the lower structure includes a conductive film.

15. The method as claimed in claim 11, further comprising forming a lower structure on the substrate before forming the yttrium-containing film,
wherein:
the yttrium-containing film is formed in contact with the lower structure, and
the lower structure includes an insulating film.

16. The method as claimed in claim 11, wherein R¹ is a C2-C5 fluoroalkyl group.

17. The method as claimed in claim 11, wherein:
L is a group represented by General formula (L-1), and
R² is a substituted or unsubstituted C3-C5 branched alkyl group.

18. The method as claimed in claim 11, wherein:
L is a group represented by General formula (L-1), and
R³ is a group represented by General formula (L-3).

19. The method as claimed in claim 11, wherein:
L is a group represented by General formula (L-1), and
R⁴ is a substituted or unsubstituted methyl group or a substituted or unsubstituted ethyl group.

20. A raw material for forming an yttrium-containing film, the raw material comprising an yttrium compound represented by General formula (1): 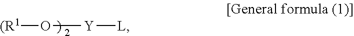
wherein, in General formula (1),
R¹ is an unsubstituted C1-C8 straight-chain or branched alkyl group or a fluorine-substituted C1-C8 straight-chain or branched alkyl group, and
L is a group represented by General formula (L-1) or General formula (L-2), 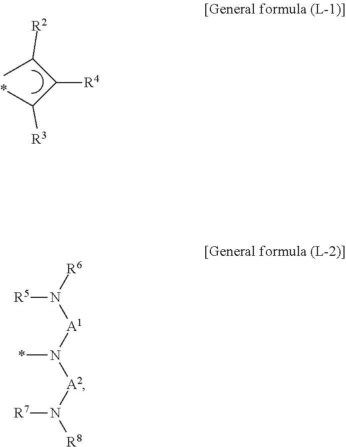
wherein, in General formula (L-1),
R² and R³ are each independently a substituted or unsubstituted C1-C8 straight-chain or branched alkyl group or a group represented by General formula (L-3) or General formula (L-4),
R⁴ is a hydrogen atom (H) or a substituted or unsubstituted C1-C5 straight-chain or branched alkyl group, and
* indicates a bonding position,
wherein, in General formula (L-2),
R⁵, R⁶, R⁷, and R⁸ are each independently a substituted or unsubstituted C1-C5 straight-chain or branched alkyl group,
A¹ and A² are each independently a substituted or unsubstituted C1-C5 alkanediyl group, and
* indicates a bonding position, 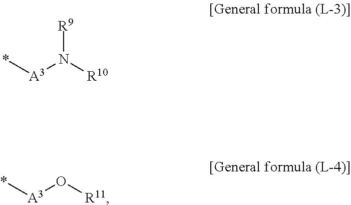
wherein, in General formulas (L-3) and (L-4),
R⁹, R¹⁰, and R¹¹ are each independently a substituted or unsubstituted C1-C5 straight-chain or branched alkyl group,
A³ and A⁴ are each independently a substituted or unsubstituted C1-C8 alkanediyl group, and
* indicates a binding position.
